(19) United States
(12) Patent Application Publication
(10) Pub. No.: US 2025/0318105 A1
(43) Pub. Date: Oct. 9, 2025

(54) SEMICONDUCTOR DEVICES

(71) Applicant: Samsung Electronics Co., Ltd., Suwon-si (KR)

(72) Inventors: Seongbin HONG, Suwon-si (KR); Jinwoo HAN, Suwon-si (KR)

(73) Assignee: Samsung Electronics Co., Ltd., Suwon-si (KR)

(21) Appl. No.: 19/072,613

(22) Filed: Mar. 6, 2025

(30) Foreign Application Priority Data
Apr. 9, 2024 (KR) 10-2024-0047873

(51) Int. Cl. H10B 12/00; H01L 23/00; H01L 25/065; H01L 25/18; H10B 80/00

(52) U.S. Cl. CPC H10B 12/30; H01L 24/08; H01L 25/0657; H01L 25/18; H10B 12/03; H10B 12/05; H10B 80/00; H01L 2224/08145; H01L 2924/1431; H01L 2924/1436

(57) ABSTRACT

A semiconductor device may include a first channel on a first region of a substrate, a first gate structure surrounding a portion of the first channel, a bit line at a first side of the first channel and electrically connected to the first channel, a capacitor at a second side of the first channel and electrically connected to the first channel, a second channel on a second region of the substrate, a second gate structure surrounding a portion of the second channel, a first source/drain pattern at a first side of the second channel and electrically connected to the second channel, and a second source/drain pattern at a second side of the second channel and electrically connected to the second channel. Heights of the first and second channels from an upper surface of the substrate may be equal to each other.

### CROSS-REFERENCE TO RELATED APPLICATION

This application claims priority under 35 U.S.C. § 119 to Korean Patent Application No. 10-2024-0047873, filed on Apr. 9, 2024 in the Korean Intellectual Property Office (KIPO), the disclosure of which is incorporated by reference herein in its entirety.

### TECHNICAL FIELD

Example embodiments of inventive concepts relate to a semiconductor device. More particularly, example embodiments of inventive concepts relate to a three-dimensional (3D) memory device.

### DISCUSSION OF RELATED ART

A DRAM device may include word lines, bit lines, channels and capacitors. In order to increase the integration degree of the DRAM device, it may be advantageous to arrange the word lines, the bit lines, the channels and/or the capacitors more efficiently.

### SUMMARY

Example embodiments of inventive concepts provide a semiconductor device having improved and/or enhanced electrical characteristics.

According to some example embodiments of inventive concepts, a semiconductor device may include a substrate including a first region and a second region; a first channel on the first region of the substrate; a first gate structure surrounding a portion of the first channel; a bit line at a first side of the first channel, the bit line being electrically connected to the first channel; a capacitor at a second side of the first channel, the capacitor being electrically connected to the first channel; a second channel on the second region of the substrate; a second gate structure surrounding a portion of the second channel; a first source/drain pattern at a first side of the second channel, the first source/drain pattern being electrically connected to the second channel; and a second source/drain pattern at a second side of the second channel, the second source/drain pattern being electrically connected to the second channel. A height of the first channel from an upper surface of the substrate may be equal to a height of the second channel from the upper surface of the substrate.

According to some example embodiments of inventive concepts, a semiconductor device may include a substrate including a first region and a second region; first channels extending in a first direction on the first region of the substrate and spaced apart from each other in a second direction, the first direction being parallel to an upper surface of the substrate, and the second direction being perpendicular to the upper surface of the substrate; first gate structures disposed in the second direction, each of the first gate structures extending in a third direction, the third direction being parallel to the upper surface of the substrate and crossing the first direction, and the first gate structures surrounding portions of the first channels, respectively; a bit line extending in the second direction on the substrate at a first side in the first direction of each of the first channels, the bit line being electrically connected to the first channels; a capacitor at a second side in the first direction of each of the first channels, the capacitor being electrically connected to the first channels; second channels on the second region of the substrate, each of the second channels extending in the first direction, and the second channels being spaced apart from each other in the second direction; second gate structures disposed in the second direction, each of the second gate structures extending in the third direction, and the second gate structures surrounding portions of the second channels, respectively; a first source/drain pattern at a first side in the first direction of each of the second channels on the substrate, the first source/drain pattern being electrically connected to the second channels; and a second source/drain pattern at a second side in the first direction of each of the second channels on the substrate, the second source/drain pattern being electrically connected to the second channels. The first channels and corresponding ones of the second channels may be respectively at same heights from an upper surface of the substrate.

According to some example embodiments of inventive concepts, a semiconductor device may include a first substrate; a second substrate; first channels on a memory cell region of the first substrate, the first substrate including the memory cell region and a first peripheral circuit region, each of the first channels extending in a first direction, the first direction being parallel to an upper surface of the first substrate, and the first channels being spaced apart from each other in a second direction, the second direction being perpendicular to the upper surface of the first substrate; first gate structures disposed in the second direction, each of the first gate structures extending in a third direction, the third direction being parallel to the upper surface of the first substrate and crossing the first direction, and the first gate structures surrounding portions of the first channels, respectively; conductive pads contacting end portions of the first gate structures, respectively, each of the conductive pads extending in the third direction; a bit line extending in the second direction on the first substrate at a first side in the first direction of each of the first channels, the bit line being electrically connected to the first channels; a capacitor structure at a second side in the first direction of each of the first channels, the capacitor structure being electrically connected to the first channels; second channels on the first peripheral circuit region of the first substrate, each of the second channels extending in the first direction, and the second channels being spaced apart from each other in the second direction; second gate structures disposed in the second direction, each of the second gate structures extending in the third direction, and the second gate structures surrounding portions of the second channels, respectively; a first source/drain pattern extending in the second direction on the first substrate at a first side in the first direction of each of the second channels, the first source/drain pattern being electrically connected to the second channels; a second source/drain pattern extending in the second direction on the first substrate at a second side in the first direction of each of the second channels, the second source/drain pattern being electrically connected to the second channels; wiring structures electrically connected to the bit line, the capacitor structure, the conductive pads, the first source/drain pattern, and the second source/drain pattern; and a first transistor and a second transistor on the wiring structures, the first transistor and the second transistor respectively being under a core region of the second substrate and a second peripheral circuit region of the second substrate, the second substrate including the core region and the second peripheral circuit region over the memory cell region and the first peripheral circuit region, respectively, of the first substrate, and the first transistor and the second transistor being electrically connected to the wiring structures.

Semiconductor devices according example embodiments may include the memory cell region and a lower portion of the peripheral circuit region surrounding the memory cell region. Additionally, in example embodiments, the semiconductor device may include the core region and an upper portion of the peripheral circuit region over the memory cell region and the lower portion of the peripheral circuit region, respectively. Circuit patterns may be disposed not only in the upper portion of the peripheral circuit region but also in the lower portion of the peripheral circuit region, which may enhance the integration degree of the semiconductor device.

### BRIEF DESCRIPTION OF THE DRAWINGS

FIGS. 1 to 8 are a plan view, perspective views and cross-sectional views illustrating a semiconductor device in accordance with example embodiments.

FIGS. 9 to 35 are vertical cross-sectional views and horizontal cross-sectional views illustrating a method of manufacturing a semiconductor device in accordance with example embodiments.

### DETAILED DESCRIPTION OF THE EMBODIMENTS

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

The above and other aspects and features of the semiconductor devices and/or the methods of manufacturing the same in accordance with some example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Two directions among horizontal directions that are substantially parallel to an upper surface of the substrate, which intersect each other, may be referred to as first and second directions D1 and D2, respectively, and a direction substantially vertical to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawings but also a direction opposite thereto.

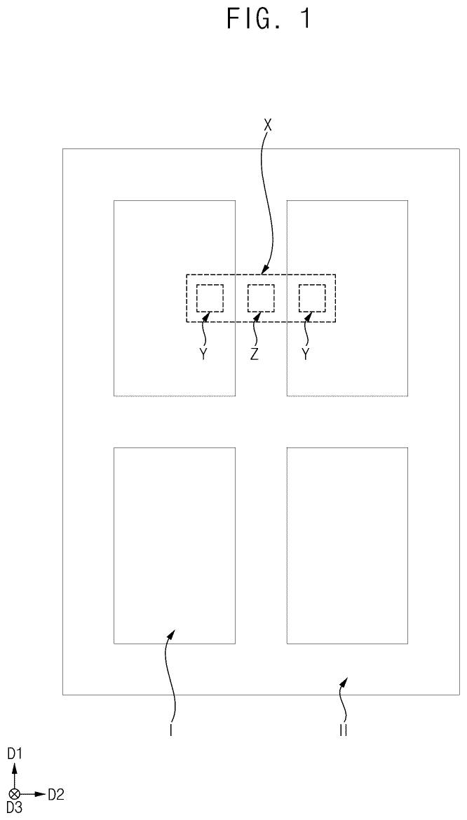

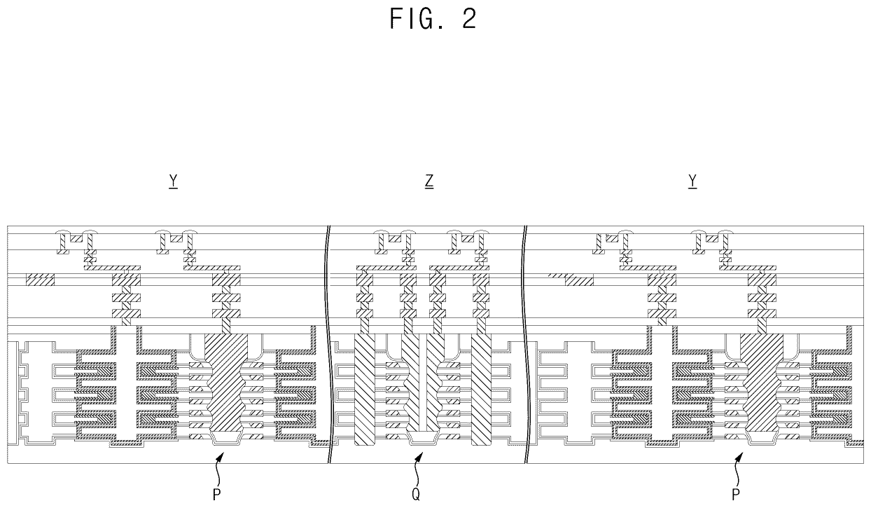

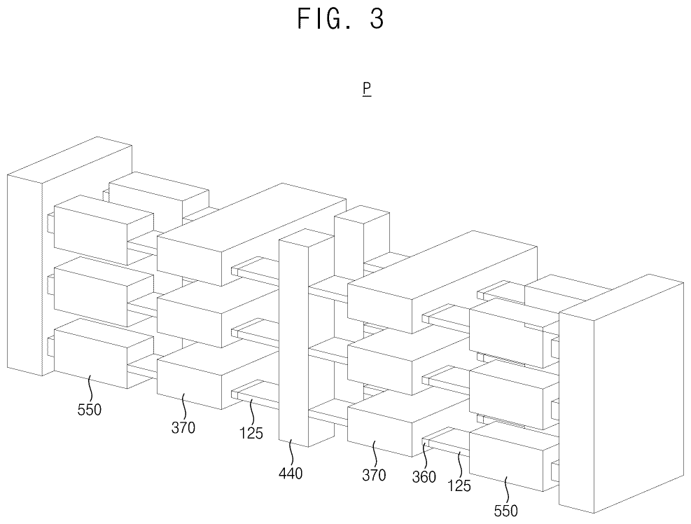

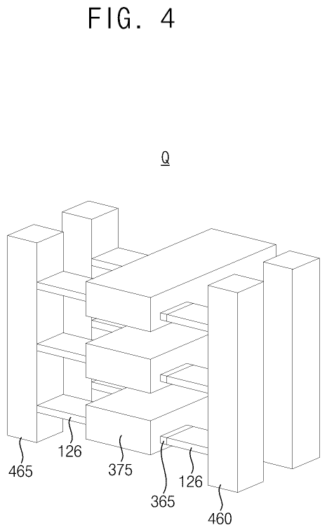

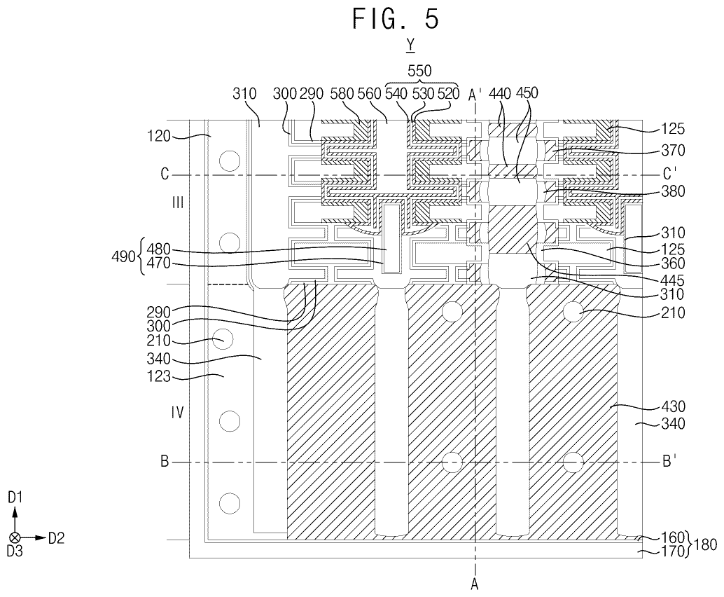

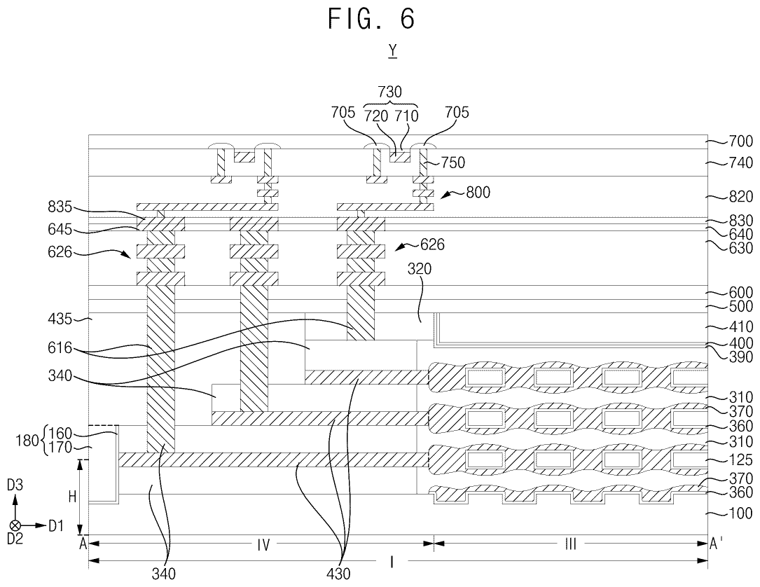

FIGS. 1 to 8 are a plan view, perspective views and cross-sectional views illustrating a semiconductor device in accordance with example embodiments. Particularly, FIG. 1 is the plan view, FIG. 2 is a vertical cross-sectional, FIGS. 3 and 4 are the perspective views, FIG. 5 is a horizontal cross-sectional view, and FIGS. 6 to 8 are vertical cross-sectional views.

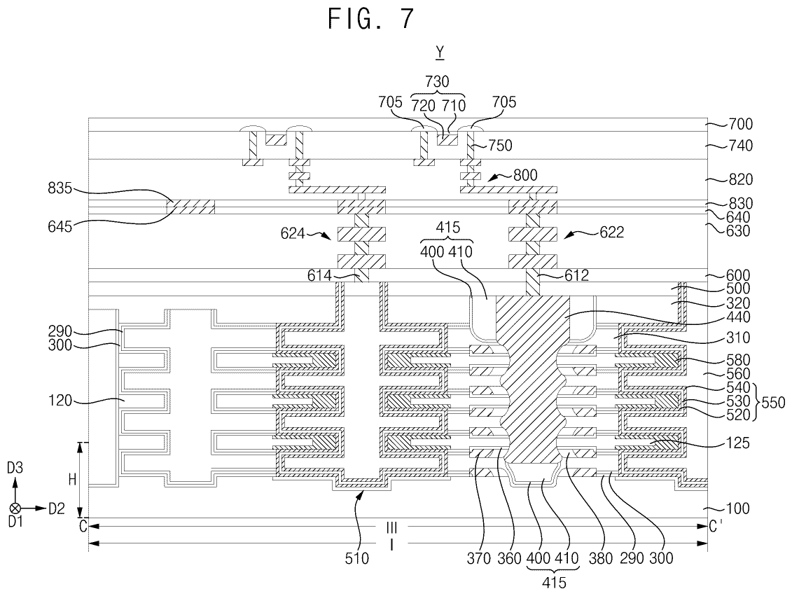

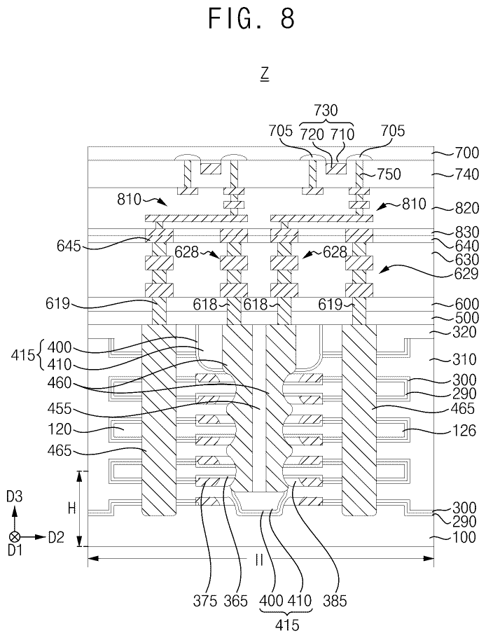

FIG. 1 is a plan view illustrating areas included in the semiconductor device. FIG. 2 is a vertical cross-sectional view of a region X of FIG. 1, which is a schematic diagram showing main elements of the semiconductor device. FIGS. 3 and 4 are perspective views of regions P and Q, respectively, of FIG. 2, which is a schematic diagram showing main elements of the semiconductor device. FIG. 5 is a horizontal cross-sectional view of a region Y of FIG. 1 at a height H of FIGS. 6 to 8. FIGS. 6 and 7 are cross-sectional views of the region Y of FIG. 1 taken along line A-A′ and C-C′, respectively, of FIG. 5. FIG. 8 is a vertical cross-sectional view of a region Z of FIG. 1.

Referring to FIGS. 1 to 8, the semiconductor device may include first and second regions I and II.

In some example embodiments, the first region I may be a memory cell region in which memory cells are formed, and the second region II may be a peripheral circuit region in which circuit patterns for applying electrical signals to the memory cells are formed. The first region I may include memory cell block regions, each of which may include memory cells, and the memory cell block regions may be arranged in each of the first and second directions D1 and D2, and may be separated from each other by a first division structure 180.

The first division structure 180 may contact an upper surface of the first region I of the first substrate 100, and may have a lattice shape in a plan view. In an example embodiment, the first division structure 180 may include a first division pattern 170 and a second division pattern 170 covering a sidewall and a lower surface of the first division pattern 170. The first division pattern 160 may include an insulating nitride, e.g., silicon nitride, and the second division pattern 170 may include an oxide, e.g., silicon oxide.

Each of the memory cell block regions may include third and fourth regions III and IV The third region III may be a memory cell array region in which a memory cell array including the memory cells is formed, and the fourth region IV may be a pad region or an extension region in which contact plugs for transferring electrical signals to the memory cell array or conductive pads contacting the contact plugs are formed.

In example embodiments, the fourth region IV may be disposed at one side or opposite sides in the first direction D1 of the third region III. FIG. 5 shows a portion of the memory cell block region, that is, a portion of each of the third and fourth regions III and IV.

In the specification, each of the first to fourth regions I, II, III and IV may be defined in an inside of the first substrate 100 and/or the second substrate 700 on which the semiconductor device is formed, or may also be defined in a space over and under the first substrate 100 and/or the second substrate 700.

In example embodiments, the semiconductor device may have a periphery over cell (POC) structure or a cell over periphery (COP) structure. Thus, some of the circuit patterns may be disposed not only in the peripheral circuit region but also over or under the memory cells in the memory cell region. FIGS. 1 to 8 show that some of the circuit patterns are disposed over the memory cells so that the semiconductor device has a POC structure.

In some cases, an upper portion of the memory cell region, that is, a region in which some of the circuit patterns are formed may be referred to as a core region, and a lower portion of the memory cell region, that is, a region in which the memory cells are formed may be referred to as a memory cell region.

As the semiconductor device has a POC structure, the peripheral circuit region may have upper and lower portions, which may be referred to as first and second peripheral circuit regions, respectively. Some of the circuit patterns may be disposed at an upper portion of the peripheral circuit region, and others of the circuit patterns may be disposed at a lower portion of the peripheral circuit region. The circuit patterns disposed at the lower portion of the peripheral circuit region may include first transistors, and as illustrated below, the first transistors may have structures that are similar to those of the memory cells in the memory cell region.

The memory cell region and the core region may be differentiated from each other by a bonding layer structure including first and second bonding layers 640 and 830, and the upper and lower portions of the peripheral circuit region may also be differentiated from each other by the bonding layer structure including the first and second bonding layers 640 and 830.

The semiconductor device may include a first channel 125, a first gate structure, a bit line 440, a capacitor structure, a conductive pad 430, first to third contact plugs 612, 614 and 616, and first to third wiring structures 622, 624 and 626 on the first region I of the first substrate 100, and a second channel 126, a second gate structure, first and second source/drain patterns 460 and 465, fourth and fifth contact plugs 618 and 619, and fourth and fifth wiring structures 628 and 629 on the second region II of the first substrate 100.

Additionally, the semiconductor device may include a dummy bit line 445, a blocking structure 490, a first division structure 180, a third division structure, a third division pattern 200, a fourth division structure 415, a support pattern 210, a semiconductor layer 120, a semiconductor pattern 123, a second mask 320, an eighth division pattern 340, eleventh and twelfth division patterns 450 and 455, second to fourth insulating interlayers 435, 600 and 630 and a capping layer 500 on the first substrate 100.

Furthermore, the semiconductor device may include a second transistor, a sixth contact plug 750 and a sixth wiring structure 800 under the first region I of the second substrate 700, and a third transistor, a seventh contact plug 755 and a seventh wiring structure 810 under the second region II of the second substrate 700.

The semiconductor device may further include fifth and sixth insulating interlayers 740 and 820 under the second substrate 700, and the bonding layer structure may be disposed between the fourth insulating interlayer 630 on the first substrate 100 and the sixth insulating interlayer 820 under the second substrate 700.

Each of the first and second substrates 100 and 700 may include a semiconductor material, e.g., silicon, germanium, silicon-germanium, etc., or a III-V group compound semiconductor, such as GaP, GaAs, GaSb, etc. In an example embodiment, each of the first and second substrates 100 and 700 may be a silicon-on-insulator (SOI) substrate or a germanium-on-insulator (GOI) substrate.

The first channel 125 may extend in the second direction D2 on the third region III of the first substrate 100, and a plurality of first channels 125 may be spaced apart from each other in the first direction D1 to form a first channel column at a height from the upper surface of the first substrate 100. In example embodiments, a plurality of first channel columns may be spaced apart from each other in the second direction D2 to form a first channel array. Additionally, a plurality of first channels 125 may be spaced apart from each other in the third direction D3, so that a plurality of first channel columns may be spaced apart from each other in the third direction D3 and a plurality of first channel arrays may be spaced apart from each other in the third direction D3.

The semiconductor layer 120 may extend in the first direction D1 at each of opposite sides in the second direction D2 on the third region III of the first substrate 100. In example embodiments, the semiconductor layer 120 and the first channel 125 may be disposed at substantially the same height from the upper surface of the first substrate 100.

The second channel 126 may extend in the second direction D2 on the second region II of the first substrate 100, and a plurality of second channels 126 may be spaced apart from each other in the first direction D1 to form a second channel column. In example embodiments, a plurality of second channel columns may be spaced apart from each other in the second direction D2 to form a second channel array. Additionally, a plurality of second channels 126 may be spaced apart from each other in the third direction D3, so that a plurality of second channel columns may be spaced apart from each other in the third direction D3 and a plurality of second channel arrays may be spaced apart from each other in the third direction D3. In example embodiments, each of the second channels 126 may be disposed at a height substantially the same as that of a corresponding one of the first channels 125.

The semiconductor pattern 123 may extend in the first direction D1 at each of opposite sides in the second direction D2 on the fourth region IV of the first substrate 100. The semiconductor pattern 123 may contact and be connected to the semiconductor layer 120. In example embodiments, the semiconductor pattern 123 and the second channel 126 may be disposed at substantially the same height from the upper surface of the first substrate 100.

Each of the first and second channels 125 and 126, the semiconductor layer 120 and the semiconductor pattern 123 may include substantially the same material, e.g., a semiconductor material such as silicon.

The first gate structure may surround an end portion in the second direction D2 of the first channel 125, and may include a first gate electrode 370, a first gate insulation pattern 360 and a first gate mask 380. In example embodiments, the first gate structure may extend in the first direction D1 and surround end portions of the first channels 125 in each of the first channel columns on the third region III of the first substrate 100, and a plurality of first gate structures may be spaced apart from each other in the second direction D2. Each of the first gate structures may serve as a word line of the semiconductor device.

The first gate insulation pattern 360 may cover lower and upper surfaces and opposite sidewalls in the first direction D1 of the end portion of the first channel 125. The first gate insulation pattern 360 may include an oxide, e.g., silicon oxide.

The first gate electrode 370 may cover lower and upper surfaces and opposite sidewalls in the first direction D1 of a portion of the first gate insulation pattern 360. In example embodiments, the first gate electrode 370 may extend in the first direction D1, and may cover the portions of ones of the first gate insulation patterns 360 disposed in the first direction D1. The first gate electrode 370 may include a conductive material, e.g., a metal, a metal nitride, a metal silicide, etc.

The first gate mask 380 may cover lower and upper surfaces and opposite sidewalls in the first direction D1 of a portion of the first gate insulation pattern 360, and may contact a sidewall in the second direction D2 of the first gate electrode 370. The first gate mask 380 may include an insulating nitride, e.g., silicon nitride.

The conductive pad 430 may extend in the first direction D1 on the fourth region IV of the first substrate 100, and a plurality of conductive pads 430 may be spaced apart from each other in the second direction D2. In example embodiments, at least a portion of the conductive pad 430 may be disposed at substantially the same height as the first gate electrode 370, and may contact a sidewall in the first direction D1 of the first gate electrode 370 to be electrically connected thereto. In example embodiments, the conductive pad 430 may overlap the first gate structure and the first channel 125 in the first direction D1.

In example embodiments, a plurality of conductive pads 430 may be spaced apart from each other in the third direction D3, and lengths in the first direction D1 of the conductive pads 430 may decrease from a lowermost one to an uppermost one thereof in a stepwise manner. Thus, the conductive pads 430 disposed in the third direction D3 may form a staircase structure.

The conductive pad 430 may include a conductive material, e.g., a metal, a metal nitride, a metal silicide, doped polysilicon, etc.

The second gate structure may surround an end portion in the second direction D2 of the second channel 126, and may include a second gate electrode 375, a second gate insulation pattern 365 and a second gate mask 385. In example embodiments, the second gate structure may extend in the first direction D1 and surround end portions of the second channels 126 in each of the second channel columns on the second region II of the first substrate 100, and a plurality of second gate structures may be spaced apart from each other in the second direction D2.

The second gate insulation pattern 365 may cover lower and upper surfaces and opposite sidewalls in the first direction D1 of the end portion of the second channel 126. The second gate insulation pattern 365 may include an oxide, e.g., silicon oxide.

The second gate electrode 375 may cover lower and upper surfaces and opposite sidewalls in the first direction D1 of a portion of the second gate insulation pattern 365. In example embodiments, the second gate electrode 375 may extend in the first direction D1, and may cover the portions of ones of the second gate insulation patterns 365 disposed in the first direction D1. The second gate electrode 375 may include a conductive material, e.g., a metal, a metal nitride, a metal silicide, etc.

The second gate mask 385 may cover lower and upper surfaces and opposite sidewalls in the first direction D1 of a portion of the second gate insulation pattern 365, and may contact a sidewall in the second direction D2 of the second gate electrode 375. The second gate mask 385 may include an insulating nitride, e.g., silicon nitride.

In example embodiments, the first and second gate structures may be disposed at substantially the same height from the upper surface of the first substrate 100. In example embodiments, the second gate insulation pattern 365, the second gate electrode 375 and the second gate mask 385 may be disposed at substantially the same height and may include substantially the same materials as the first gate insulation pattern 360, the first gate electrode 370 and the first gate mask 380, respectively.

In example embodiments, the third division structure may include first and second insulation patterns 290 and 300 and a seventh division pattern 310.

The third division structure may be disposed on the first and second regions I and II of the first substrate 100, and may fill spaces between the first gate structures, between the first channels 125, between the semiconductor layers 120, between the second gate structures and between the second channels 126 that are stacked in the third direction D3, between the upper surface of the first substrate 100 and each of a lowermost one of the first gate structure and a lowermost one of the second gate structure, between the upper surface of the first substrate 100 and each of a lowermost one of the first channels 125, a lowermost one of the second channels 126 and a lowermost one of the semiconductor layers 120, and between the second mask 320 and each of an uppermost one of the first gate structure, an uppermost one of the second gate structure, an uppermost one of the first channels 125, an uppermost one of the second channels 126 and an uppermost one of the semiconductor layers 120. Additionally, the third division structure may fill spaces between ones of the first channels neighboring in the second direction D2, between ones of the second channels 126 neighboring in the second direction D2, and between the first channel 125 and the semiconductor layer 120.

Furthermore, the third division structure may be disposed between ones of the first channels 125 on the first region I of the first substrate 100 and between ones of the second channels 126 on the second region II of the first substrate 100.

The first and second insulation patterns 290 and 300 may be sequentially stacked on a surface of each of the first and second channels 125 and 126, and the seventh division pattern 310 may be disposed on the second insulation pattern 300 and fill other portions of the spaces.

The first insulation pattern 290 and the seventh division pattern 310 may include an oxide, e.g., silicon oxide, and the second insulation pattern 300 may include an insulating nitride, e.g., silicon nitride.

The eighth division pattern 340 may be disposed on the fourth region IV of the first substrate 100, and may fill spaces between conductive pads 430 and between semiconductor patterns 123 that are stacked in the third direction D3, between the upper surface of the first substrate 100 and each of the conductive pad 430 and the semiconductor pattern 123, and between the second mask 320 and each of an uppermost one of the conductive pads 430 and an uppermost one of the semiconductor patterns 123.

Additionally, the eighth division pattern 340 may be disposed ones of the conductive pads 430 neighboring in the first direction D1 and between the semiconductor patterns 123 and the conductive pads 430 neighboring in the first direction D1 on the fourth region IV of the first substrate 100.

In example embodiments, lengths in the first direction D1 of the eighth division patterns 340 disposed in the third direction D3 may decrease from a lowermost one to an uppermost one in a stepwise manner, and thus a stack structure including the eighth division patterns 340 may be a staircase structure. In example embodiments, one of the eighth division patterns 340 on a corresponding one of the conductive pads 430 may collectively form one step layer, and a sidewall in the first direction D1 of each of the eighth division patterns 340 may be aligned with a sidewall in the first direction D1 of the corresponding one of the conductive pads 430 in the third direction D3.

The eighth division pattern 340 may include an insulating nitride, e.g., silicon nitride.

The support pattern 210 may be disposed on the first and second regions I and II of the first substrate 100, and may extend through the semiconductor layers 120, the third division structure, the eighth division pattern 340 and the conductive pads 430 to contact the upper surface of the first substrate 100. A plurality of support patterns 210 may be spaced apart from each other in the first direction D1 at each of opposite sides in the second direction D2 of the third region III of the first substrate 100, and a plurality of support patterns 210 may be spaced apart from each other in each of the first and second directions D1 and D2 on the fourth region IV of the first substrate100. Additionally, a plurality of support patterns 210 may be spaced apart from each other on an edge portion of the second region II of the first substrate 100.

The support pattern 210 may include an insulating nitride, e.g., silicon nitride, and may be merged with the eighth division pattern 340.

The second mask 320 may be disposed on the third division structure and the eighth division pattern 340 on the first and second regions I and II of the first substrate 100. However, the eighth division pattern 340 may cover a sidewall of the second mask 320, and thus an upper surface of the second mask 320 may be substantially coplanar with an upper surface of the eighth division pattern 340. The second mask 320 may include an insulating nitride, e.g., silicon nitride.

The second insulating interlayer 435 may be disposed on the eighth division pattern 340 on the fourth region IV of the first substrate 100. In example embodiments, an upper surface of the second insulating interlayer 435 may be substantially coplanar with the upper surface of the second mask 320. The second insulating interlayer 435 may include an oxide, e.g., silicon oxide.

The fourth division structure 415 may be disposed between ones of the first channels 125 neighboring in the second direction D2 or between ones of the second channels 126 neighboring in the second direction D2 on the first and second regions I and II of the first substrate 100. In example embodiments, the fourth division structure 415 may extend in the first direction D1 on each of the second and third regions II and III of the first substrate 100, and a plurality of fourth division structures 415 may be spaced apart from each other in the second direction D2. In example embodiments, an upper surface of the fourth division structure 415 may be substantially coplanar with the upper surface of the second mask 320.

The fourth division structure 415 may include a ninth division pattern 410 and a fourth insulation pattern 400 covering a sidewall and a lower surface of the ninth division pattern 410. The fourth insulation pattern 400 may include an insulating nitride, e.g., silicon nitride, and the ninth division pattern 410 may include an oxide, e.g., silicon oxide.

The bit line 440 may extend in the third direction D3 partially through the fourth division structure 415 extending in the first direction D1 on the third region III of the first substrate 100, and a plurality of bit lines 440 may be spaced apart from each other in the first direction D1. An eleventh division pattern 450 including an oxide, e.g., silicon oxide may extend partially through the fourth division structure 415 between ones of the bit lines 440 neighboring in the first direction D1, so that the bit lines 440 may be separated from each other by the eleventh division pattern 450. The dummy bit line 445 may be disposed on a portion of the third region III adjacent to the fourth region IV of the first substrate 100.

In example embodiments, each of the bit line 440 and the dummy bit line 445 may contact ones of the first channels 125 that are disposed in the third direction D3 at each of opposite sides in the second direction D2 of each of the bit line 440 and the dummy bit line 445. Each of the bit line 440 and the dummy bit line 445 may contact sidewalls in the second direction D2 of the first gate insulation pattern 360 and the first gate mask 380 that may surround an end portion of each of the first channels 125.

In an example embodiment, each of the bit line 440 and the dummy bit line 445 may include, e.g., polysilicon doped with n-type impurities. Alternatively, each of the bit line 440 and the dummy bit line 445 may include, e.g., a metal, a metal nitride, a metal silicide, etc.

The first source/drain pattern 460 may extend in the third direction D3 partially through the fourth division structure 415 extending in the first direction D1 on the second region II of the first substrate 100, and a plurality of first source/drain patterns 460 may be spaced apart from each other in each of the first and second directions D1 and D2. A twelfth division pattern 455 may extend partially through the fourth division structure 415 between the first source/drain patterns 460, and may separate the first source/drain patterns 460 from each other. The twelfth division pattern 455 may include an oxide, e.g., silicon oxide.

In example embodiments, two first source/drain patterns 460 may be disposed between ones of the second channels 126 neighboring in the second direction D2, and may contact sidewalls in the second direction D2 of the second channels 126, respectively, disposed in the third direction D3. Each of the first source/drain patterns 460 may contact sidewalls in the second direction D2 of the second gate insulation pattern 365 and the second gate mask 385 surrounding an end portion of each of the second channels 126.

The second source/drain pattern 465 may extend in the third direction D3 partially through the third division structure and the second channels 126 on the second region II of the first substrate 100, and a plurality of second source/drain patterns 465 may be spaced apart from each other in each of the first and second directions D1 and D2. The second source/drain patterns 465 may overlap the first source/drain patterns 460, respectively, in the second direction D2.

In an example embodiment, each of the first and second source/drain patterns 460 and 465 may include polysilicon doped with n-type impurities. Alternatively, each of the first and second source/drain patterns 460 and 465 may include polysilicon doped with p-type impurities.

In example embodiments, upper and lower surfaces of the first source/drain pattern 460 may be substantially coplanar with upper and lower surfaces, respectively, of the bit line 440, and the first source/drain pattern 460 may include a material substantially the same as that of the bit line 440.

The second gate structure, the second channel 126 and the first and second source/drain patterns 460 and 465 on the second region II of the first substrate 100 may collectively form a first transistor.

The blocking structure 490 may extend the third division structure between ones of the first channels 125 neighboring in the second direction D2 on a portion of the third region III adjacent to the fourth region IV of the first substrate 100, and may contact the upper surface of the first substrate 100. The blocking structure 490 may be disposed at an opposite side of the bit line 440 with respect to the first channel 125. In an example embodiment, the blocking structure 490 may have a shape of, e.g., polygon such as a rectangle in a plan view, however, inventive concepts are not limited thereto.

In example embodiments, the blocking structure 490 may include a second blocking pattern 480 extending in the third direction D3 and a first blocking pattern 470 covering a sidewall and a lower surface of the second blocking pattern 480. The first blocking pattern 470 may include an insulating nitride, e.g., silicon nitride, and the second blocking pattern 480 may include an oxide, e.g., silicon oxide.

The capacitor structure may include a capacitor 550 and a plate electrode 560, and the capacitor 550 may include first and second capacitor electrodes 520 and 540 and a dielectric pattern 530.

In example embodiments, the first capacitor electrode 520, the dielectric pattern 530 and the second capacitor electrode 540 may be sequentially stacked in spaces between ones of the first channels 125 stacked in the third direction D3, between a lowermost one of the first channels 125 and the upper surface of the first substrate 100 and between an uppermost one of the first channels 125 and the second mask 320 on the third region III of the first substrate 100, and the plate electrode 560 may fill a remaining portion of the spaces and a space between ones of the first channels 125 neighboring in the second direction D2.

Thus, the plate electrode 560 may include a vertical extension portion extending in the third direction D3 and a horizontal extension portion extending from each of opposite sidewalls in the second direction D2. Each of the capacitor 550 and the plate electrode 560 may extend in the first direction D1 on the third region III of the first substrate 100.

In example embodiments, the capacitor structure may extend through the capping layer 500 and the third division structure, and may contact a sidewall in the first direction D1 of the blocking structure 490. Thus, the capacitor structure may be disposed at an opposite side of the bit line 440 in the second direction D2 with respect to the first channel 125.

A metal silicide pattern 580 may be disposed at a portion of each of the first channels 125 contacting the first capacitor electrode 520.

Each of the first and second capacitor electrodes 520 and 540 may include a metal, e.g., titanium, tantalum, etc., or a metal nitride, e.g., titanium nitride, tantalum nitride, etc., the dielectric pattern 530 may include a metal oxide having a high dielectric constant, e.g., hafnium oxide, zirconium oxide, etc., the plate electrode 560 may include, e.g., doped or undoped silicon-germanium, and the metal silicide pattern 580 may include, e.g., titanium silicide, tantalum silicide, etc.

The word line and the bit line 440 extending in the first and second directions D1 and D2, respectively, the first channel 125 surrounded by the word line and contacting the bit line 440, and the capacitor electrode 550 electrically connected to the first channel 125 on the third region III of the first substrate 100 may collectively form the memory cell, and a plurality of memory cells may be disposed in each of the first to third directions D1, D2 and D3 on the third region III of the first substrate 100.

The capping layer 500 may be disposed on the second mask 320, the second insulating interlayer 435 and the fourth division structure 415 on the first and second regions I and II of the first substrate 100, and may cover a sidewall of an upper portion of the capacitor structure. The capping layer 500 may include an insulating nitride, e.g., silicon nitride.

The third and fourth insulating interlayers 600 and 630, the first and second bonding layers 640 and 830, the sixth and fifth insulating interlayers 820 and 740 and the second substrate 700 may be sequentially stacked on the capping layer 500 in the third direction D3.

The first contact plug 612 may extend through the third insulating interlayer 600 and the capping layer 500 to contact an upper surface of the bit line 440, the second contact plug 614 may extend through the third insulating interlayer 600 to contact an upper surface of the plate electrode 560 of the capacitor structure, the third contact plug 616 may extend through the third insulating interlayer 600, the capping layer 500, the second mask 320 and the eighth division pattern 340 or extend through the third insulating interlayer 600, the capping layer 500 and the second insulating interlayer 435 to contact an upper surface of the conductive pad 430, and the fourth and fifth contact plugs 618 and 619 may extend through the third insulating interlayer 600 and the capping layer 500 to contact upper surfaces of the first and second source/drain patterns 460 and 465, respectively.

The first to fifth wiring structures 622, 624, 626, 628 and 629 may be disposed in the fourth insulating interlayer 630 to contact upper surfaces of the first to fifth contact plugs 612, 614, 616, 618 and 619, respectively. The first and second bonding layers 640 and 830 may include first and second bonding patterns 645 and 835, respectively. The first and second bonding patterns 645 and 835 may contact each other, and each of the first bonding patterns 645 may contact a corresponding one of the first to fifth wiring structures 622, 624, 626, 628 and 629 to be electrically connected thereto.

The sixth and seventh wiring structures 800 and 810 may be disposed in the sixth insulating interlayer 820, and may contact corresponding ones of the second bonding patterns 835, respectively, to be electrically connected thereto. The sixth and seventh contact plugs 750 and 755 may be disposed in the fifth insulating interlayer 740, and may contact the sixth and seventh wiring structures, respectively.

The first to third contact plugs 612, 614 and 616, the sixth contact plug 750, the first to third wiring structures 622, 624 and 626 and the sixth wiring structure 800 may be disposed on the first region I of the first substrate 100, that is, under the first region I of the second substrate 700, and the fourth, fifth and seventh contact plugs 618, 619 and 755 and the fourth, fifth and seventh wiring structures 628, 619 and 755 may be disposed on the second region II of the first substrate 100, that is, under the second region II of the second substrate 700.

A third gate structure 730 including a third gate insulation pattern 710 and a third gate electrode 720 may be disposed under the first region I of the second substrate 700, and first impurity regions 705 may be disposed at lower portions, respectively, of the second substrate 700 adjacent to the third gate structure 730. The third gate structure 730 and the first impurity regions 705 may collectively form a second transistor. Additionally, a fourth gate structure 735 including a fourth gate insulation pattern 715 and a fourth gate electrode 725 may be disposed under the first region I of the second substrate 700, and second impurity regions 707 may be disposed at lower portions, respectively, of the second substrate 700 adjacent to the fourth gate structure 735. The fourth gate structure 735 and the second impurity regions 707 may collectively form a third transistor.

In the semiconductor device, the memory cells may be disposed in the memory cell region, and the first transistor having a structure similar to that of the memory cell may be disposed in a lower portion of the peripheral circuit region.

That is, the first transistor may include the second gate structure, the second channel 126 and the first and second source/drain patterns 460 and 465, which may have structures similar to those of the first gate structure, the first channel 125 and the bit line 440 of the memory cell.

The second transistor may be disposed in the core region over the memory cell region, and the third transistor may be disposed at an upper portion of the peripheral circuit region. The first transistor may have a function similar to that of the third transistor.

That is, the first transistor may be disposed at a lower portion of the peripheral circuit region surrounding the memory cell region, and may replace some functions of the third transistor at the upper portion of the peripheral circuit region surrounding the core region over the memory cell region. If the third transistor is disposed only at the upper portion of the peripheral circuit region and no transistor is disposed at the lower portion of the peripheral circuit region, the upper portion of the peripheral circuit region has to have a large area so as to decrease the integration degree of the semiconductor device.

However, in example embodiments, the first transistor having some functions of the third transistor may also be disposed at the lower portion of the peripheral circuit region, and thus the area of the upper portion of the peripheral circuit region may decrease, which may enhance the integration degree of the semiconductor device.

The first transistor may be formed by processes substantially the same as or similar to those for forming the memory cells in the memory cell region, instead of independent processes, so that the complexity and difficulty of the processes may not increase.

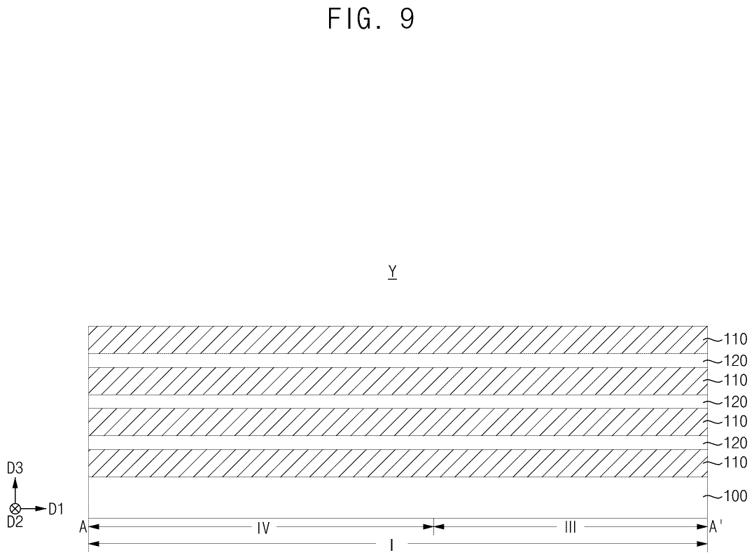

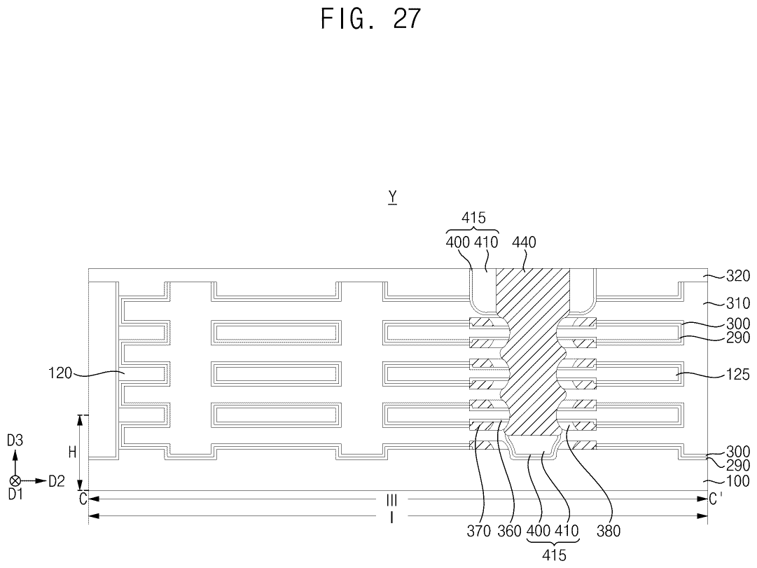

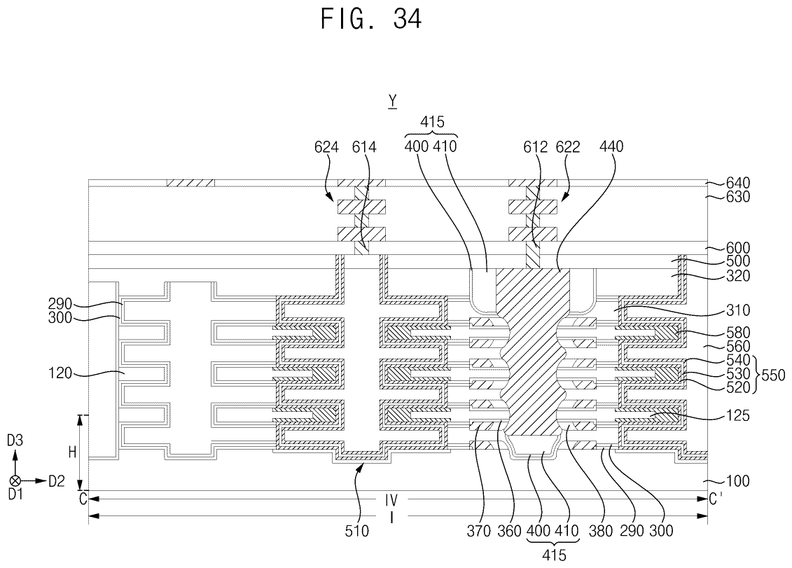

FIGS. 9 to 35 are vertical cross-sectional views and horizontal cross-sectional views illustrating a method of manufacturing a semiconductor device in accordance with example embodiments.

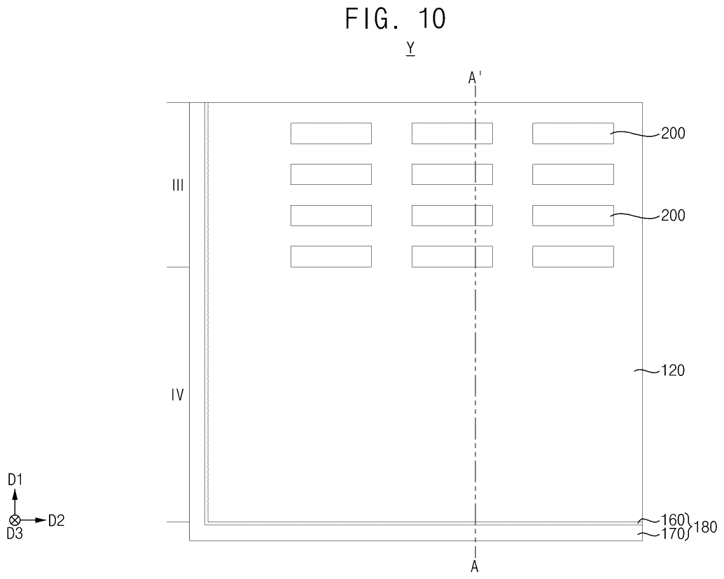

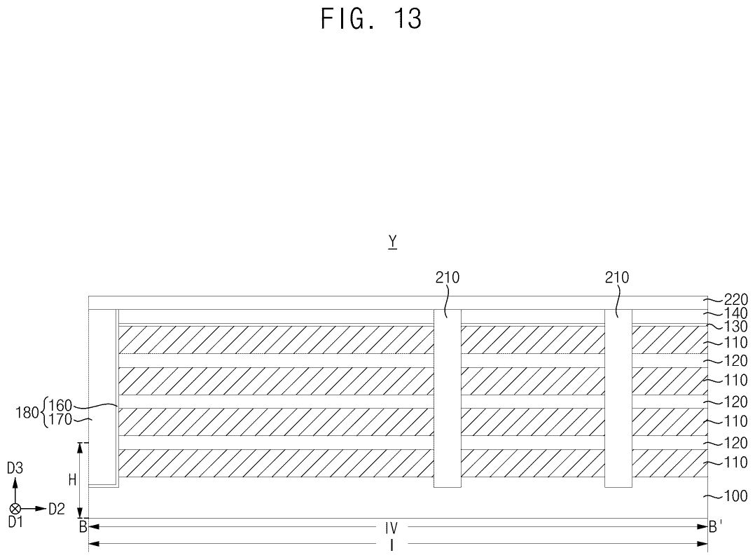

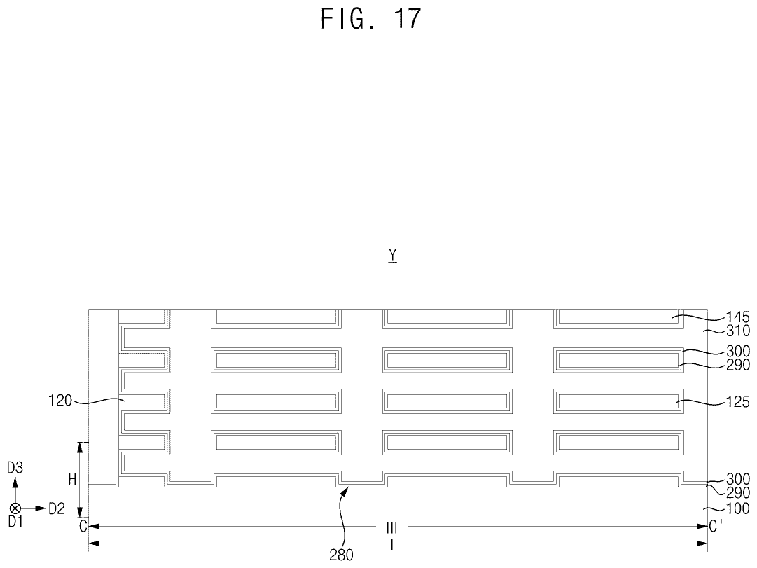

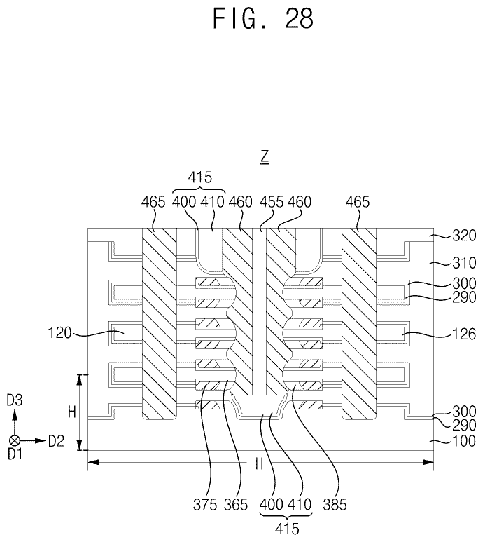

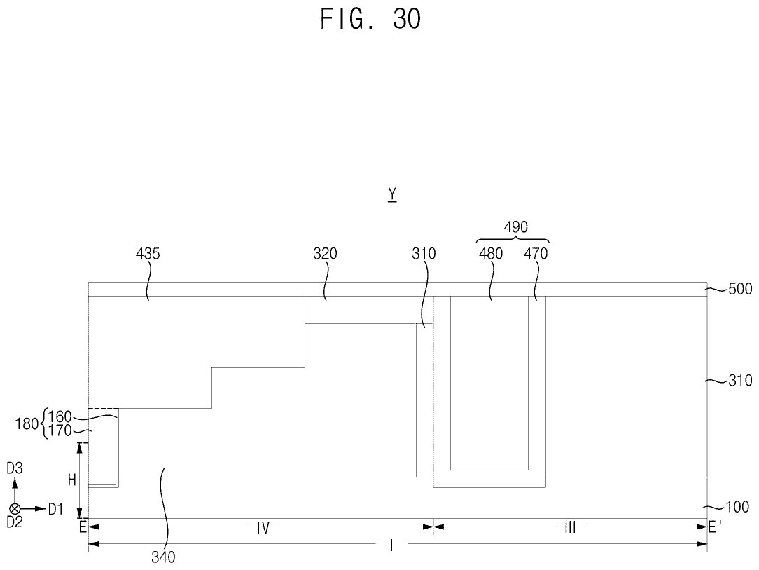

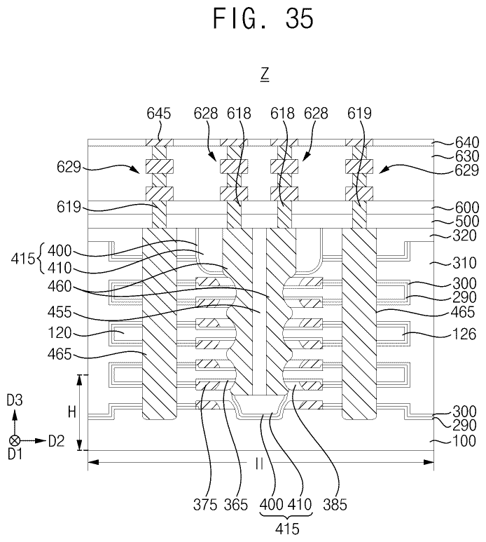

Particularly, FIGS. 10, 12, 14, 16, 18, 20, 22, 24, 26, 29 and 31 are horizontal cross-sectional views at heights H of corresponding vertical cross-sectional views, respectively, FIGS. 9, 11, 25 and 33 are vertical cross-sectional views taken along lines A-A′ of corresponding horizontal cross-sectional views, respectively, FIGS. 13, 15, 19 and 23 are vertical cross-sectional views taken along lines B-B′ of corresponding horizontal cross-sectional views, respectively, FIGS. 17, 21, 27, 32 and 34 are vertical cross-sectional views taken along lines C-C′ of corresponding horizontal cross-sectional views, respectively, and FIGS. 30 and 35 are vertical cross-sectional views taken along lines E-E′ of corresponding horizontal cross-sectional views, respectively. FIG. 28 is a vertical cross-sectional view about a second region of a first substrate.

Referring to FIG. 9, a sacrificial layer 110 and a semiconductor layer 120 may be alternately and repeatedly stacked on a first substrate 100 including first and second regions I and II (refer to FIGS. 1 and 2) to form a mold layer.

FIG. 9 shows that the sacrificial layer 110 and the semiconductor layer 120 are stacked at four levels and three levels, respectively, on the first substrate 100, and the sacrificial layer 110 and the semiconductor layer 120 may be stacked at more or less than four levels and three levels, respectively. However, example embodiments are not limited thereto.

In example embodiments, the mold layer may be formed by an epitaxial growth process using an upper surface of the first substrate 100 as a seed.

In an example embodiment, the semiconductor layer 120 may include, e.g., silicon, and the sacrificial layer 110 may include a material having a selectivity with respect to the semiconductor layer 120, e.g., silicon-germanium. However, example embodiments are not limited thereto.

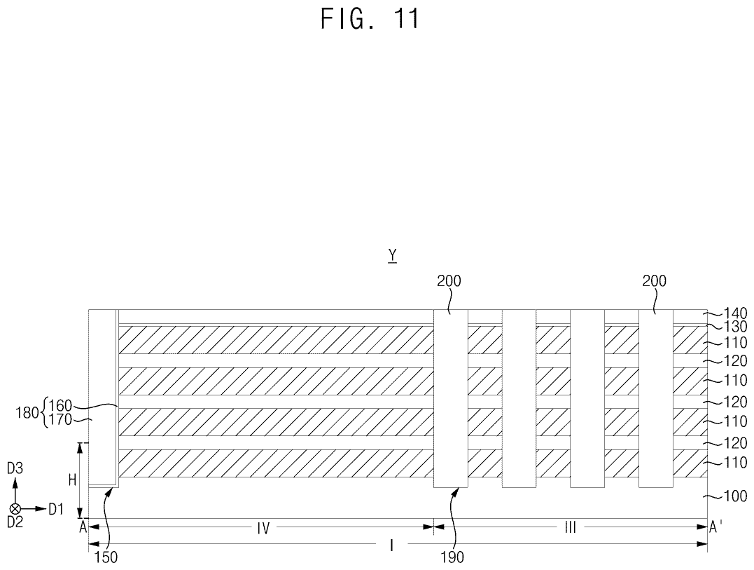

Referring to FIGS. 10 and 11, an insulation pad layer 130 and a first mask layer 140 may be sequentially stacked in the third direction D3 on the mold layer, a dry etching process may be performed on the first mask layer 140, the insulation pad layer 130 and the mold layer to form a first opening 150 exposing the upper surface of the first substrate 100, and a first division structure 180 may be formed in the first opening 150.

The insulation pad layer 130 may include an oxide, e.g., silicon oxide, and the first mask layer 140 may include an insulating nitride, e.g., silicon nitride.

In example embodiments, the first division structure 180 may have a lattice shape in a plan view, and thus a plurality of memory block regions each of which may have, e.g., a rectangular shape may be defined in each of the first and second directions D1 and D2 on the first region I of the first substrate 100. However, inventive concepts are not limited thereto, and each of the memory block regions may have other shapes in a plan view. FIG. 10 shows a portion of the first division structure 180.

In example embodiments, each of the memory block regions may include third and fourth regions III and IV arranged in the first direction D1.

In an example embodiment, the first division structure 180 may include a first division pattern 160 on a sidewall and a bottom of the first opening 150 and a second division pattern 170 fill a remaining portion of the first opening 150. A sidewall and a lower surface of the second division pattern 170 may be covered by the first division pattern 160. The first division pattern 160 may include an insulating nitride, e.g., silicon nitride, and the second division pattern 170 may include an oxide, e.g., silicon oxide.

For example, a dry etching process may be performed on the first mask layer 140, the insulation pad layer 130 and the mold layer to form a second opening 190 exposing the upper surface of the first substrate 100, and a third division pattern 200 may be formed in the second opening 190.

In example embodiments, the third division pattern 200 may have a bar shape extending in the second direction D2 in a plan view, and a plurality of third division patterns 200 may be spaced apart from each other in each of the first and second directions D1 and D2. The third division pattern 200 may include an oxide, e.g., silicon oxide.

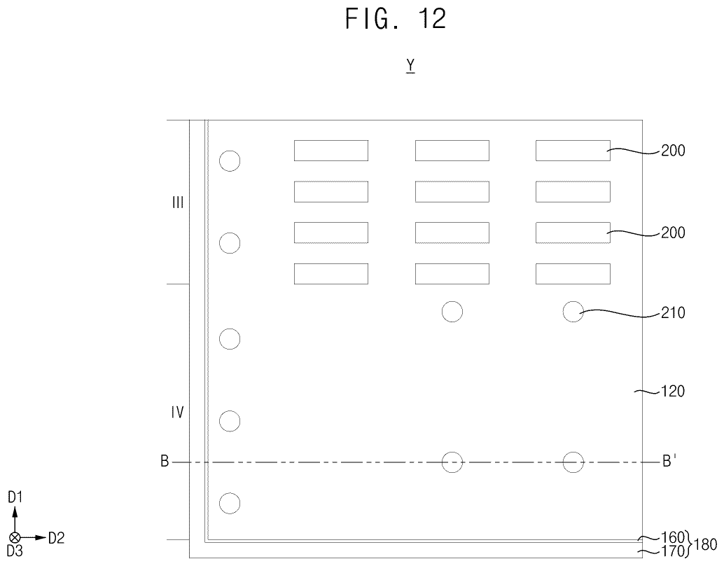

Referring to FIGS. 12 and 13, a dry etching process may be performed on the first mask layer 140, the insulation pad layer 130 and the mold layer to form a third opening exposing the upper surface of the first substrate 100, and a support pattern 210 may be formed in the third opening.

In example embodiments, the support pattern 210 may have a shape of, e.g., a circle, an ellipse, a polygon, a polygon with rounded corners, etc., in a plan view, and a plurality of support patterns 210 may be spaced apart from each other in each of the first and second directions D1 and D2. The support pattern 210 may include an insulating nitride, e.g., silicon nitride.

A first insulating interlayer 220 may be formed on the first mask layer 140, the first division structure 180, the third division pattern 200 and the support pattern 210. The first insulating interlayer 220 may include an oxide, e.g., silicon oxide.

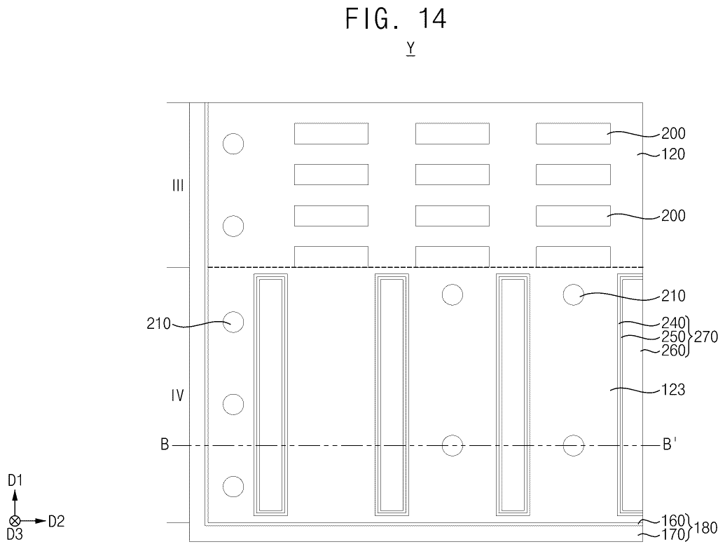

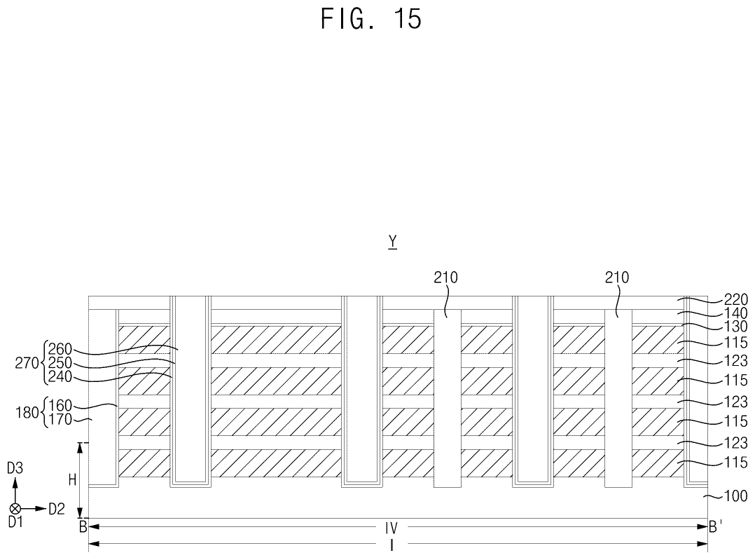

Referring to FIGS. 14 and 15, a dry etching process may be performed on the first insulating interlayer 220, the first mask layer 140, the insulation pad layer 130 and the mold layer to form a fourth opening 230 exposing the upper surface of the first substrate 100, and a second division structure 270 may be formed in the fourth opening 230.

In example embodiments, the second division structure 270 may have a bar shape extending in the first direction D1 in a plan view, and a plurality of second division structures 270 may be spaced apart from each other in the second direction D2. In example embodiments, each of the second division structures 270 may overlap in the first direction D1 a portion of the mold layer between ones of the third division patterns 300 neighboring in the second direction D2.

In an example embodiment, the second division structure 270 may include fourth to sixth division patterns 240, 250 and 260 sequentially stacked from a sidewall and a bottom of the fourth opening 230. Each of the fourth and sixth division patterns 240 and 260 may include an oxide, e.g., silicon oxide, and the fifth division pattern 250 may include an insulating nitride, e.g., silicon nitride.

As the second division structure 270 is formed, portions of the sacrificial layer 110 and the semiconductor layer 120 included in a portion of the mold layer in the fourth region IV may be transformed into a first sacrificial pattern 115 and a semiconductor pattern 123, respectively.

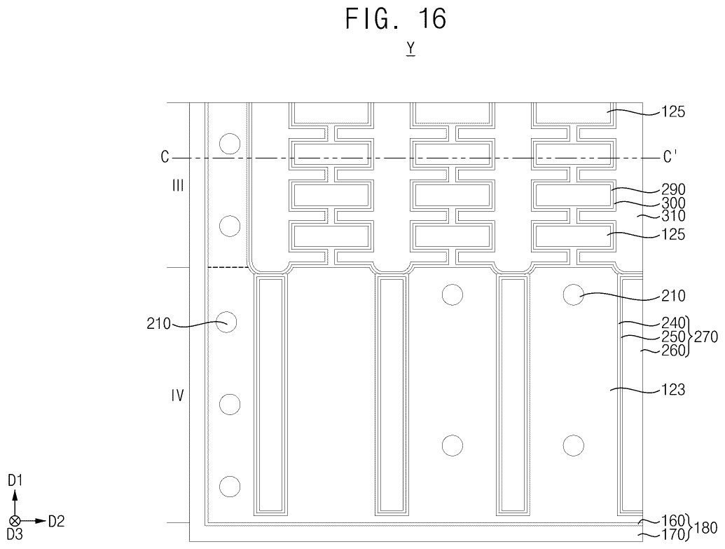

Referring to FIGS. 16 and 17, a dry etching process may be performed on the first insulating interlayer 220, the first mask layer 140, the insulation pad layer 130 and the mold layer to form a fifth opening 280 exposing the upper surface of the first substrate 100.

In example embodiments, the fifth opening 280 may extend in the first direction D1 between ones of the third division patterns 200 neighboring in the second direction D2, and a plurality of fifth openings 280 may be spaced apart from each other in the second direction D2 in the third region III. Each of the fifth openings 280 may be aligned with a corresponding one of the second division structure 270 in the first direction D1, and may extend through a portion of the fourth division pattern 240 at an end portion in the first direction D1 of the second division structure 270 to expose a sidewall of the fifth division pattern 250.

As the fifth openings 280 are formed, portions of the sacrificial layer 110 and the semiconductor layer 120 between ones of the third division patterns 200 neighboring in the first direction D1 and between the fifth openings 280 on the first region I of the first substrate 100 may be transformed into a second sacrificial pattern and a first channel 125, respectively, and portions of the insulation pad layer 130 and the first mask layer 140 on the second sacrificial pattern may remain as an insulation pad and a first mask 145.

A portion of the semiconductor layer 120 between ones of the third division patterns 200 neighboring in the first direction D1 and between the fifth openings 280 on the second region II of the first substrate 100 may be transformed into a second channel 126 (refer to FIG. 28).

A wet etching process may be performed through the fifth opening 280 to remove a portion of the second sacrificial pattern in the third region III, and most portion of the third division pattern 200 adjacent to the fifth opening 280 in the third region III and the insulation pad may also be removed.

Thus, a first gap may be formed between ones of the first channels 125 neighboring in the third direction D3, between an uppermost one of the first channels 125 and the first mask 145, and between a lowermost one of the first channels 125 and the upper surface of the first substrate 100. Additionally, the first gap may be enlarged in the first direction D1, so that a portion of the third division pattern 200 at the same level as each of the first channels 125 may remain, and other portions of the third division pattern 200 may be removed.

First and second insulation layers may be sequentially stacked on an inner wall of the first gap, a sidewall and a bottom of the fifth opening 280 and the first insulating interlayer 220, a seventh division layer may be formed on the second insulation layer to fill the first gap and the fifth opening 280, and a planarization process may be performed on the seventh division layer, the first and second insulation layers, the first insulating interlayer 220 and the second division structure 270 until an upper surface of the first mask 145 is exposed. Thus, a third division structure including first and second insulation patterns 290 and 300 and a seventh division pattern 310 in the first gap and the fifth opening 280, and the first insulating interlayer 220 may be removed.

The first insulation pattern 290 and the seventh division pattern 310 may include an oxide, e.g., silicon oxide, and the second insulation pattern 300 may include an insulating nitride, e.g., silicon nitride. The third division pattern 200 remaining between the first channels 125 or between the second channels 126 may be merged with the first insulation pattern 290, and hereinafter, the merged structure may be referred to as a first insulation pattern 290. In some embodiments, the first insulation pattern 290 and a portion of the fourth division pattern 240 exposed by the fifth opening 280 may contact each other to be merged with each other.

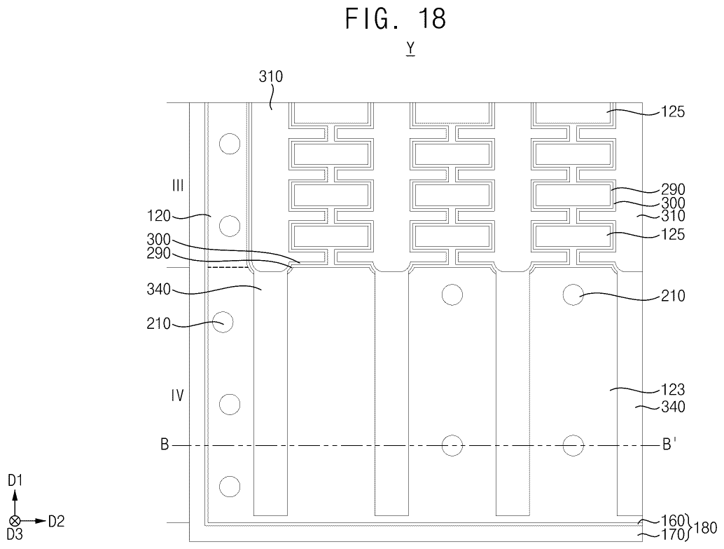

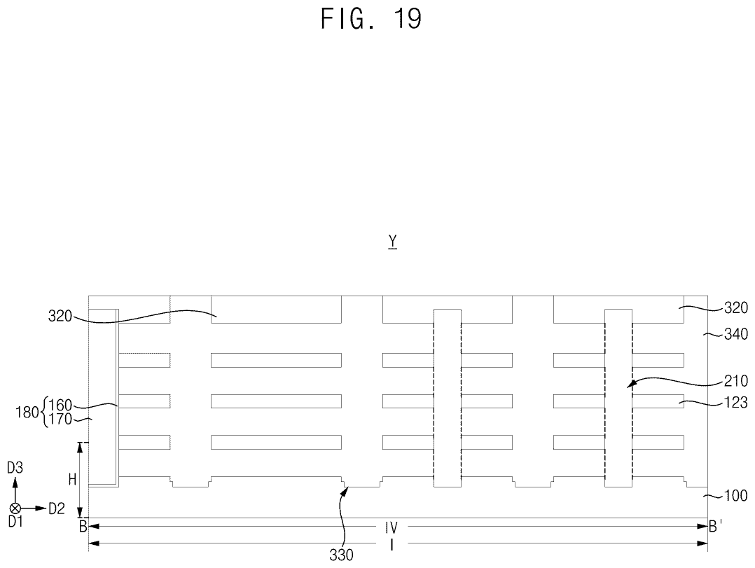

Referring to FIGS. 18 and 19, a second mask 320 may be formed on the first mask layer 140, the first mask 145, the second division structure 270 and the third division structure, a dry etching process may be performed using the second mask 320 as an etching mask to remove the second division structure 270 so that a sixth opening 330 exposing the upper surface of the first substrate 100 may be formed.

A portion of the first sacrificial pattern 115 adjacent to the sixth opening 330 may be removed through the sixth opening 330, and the insulation pad layer 130 may also be removed.

Thus, a second gap may be formed between ones of the semiconductor patterns 123 neighboring in the third direction D3, between an uppermost one of the semiconductor patterns 123 and the first mask layer, and between a lowermost one of the semiconductor patterns 123 and the first substrate 100.

The second mask 320 may include an insulating nitride, e.g., silicon nitride, and the first mask layer 140 and the first mask 145 may be merged to the second mask 320. Hereinafter, the merged structure may be referred to as the second mask 320.

An eighth division layer may be formed on the first substrate 100 and the second mask 320 to fill the second gap and the sixth opening 330, and a planarization process may be performed on the eighth division layer until an upper surface of the second mask 320 is exposed to form an eighth division pattern 340 in the second gap and the sixth opening 330. The eighth division pattern 340 may include an insulating nitride, e.g., silicon nitride, and thus, in some embodiments, the support pattern 210 may be merged to the eighth division pattern 340.

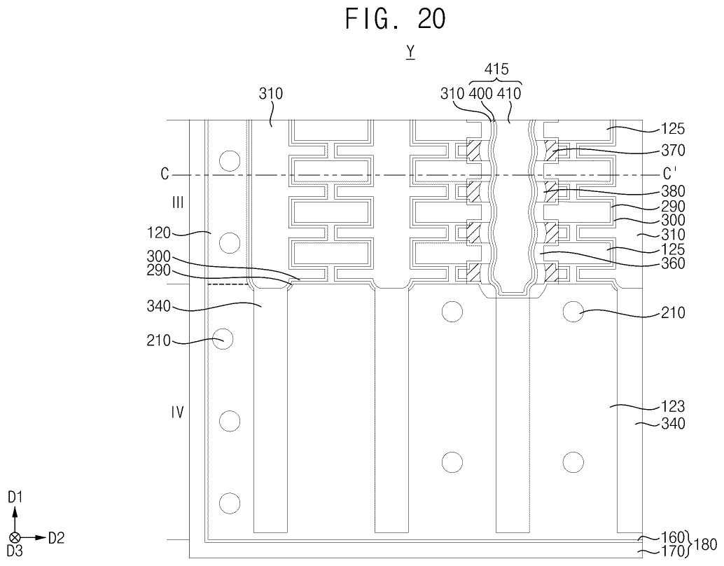

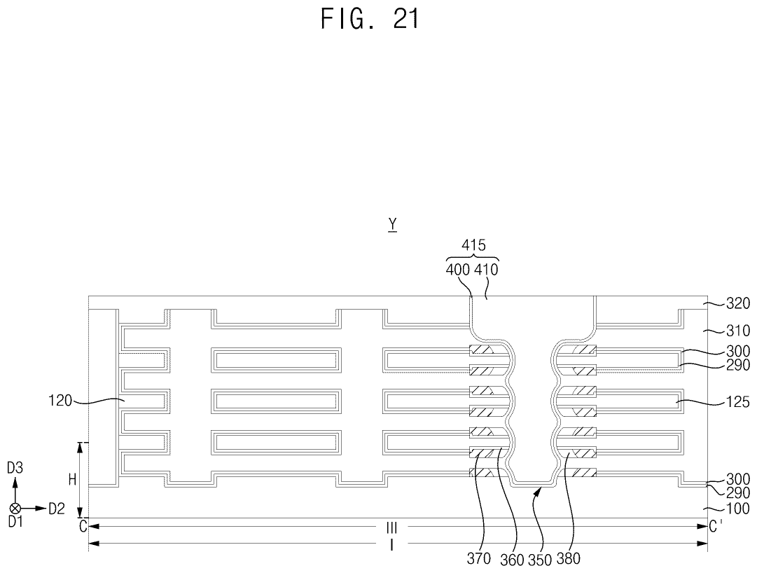

Referring to FIGS. 20 and 21, the second mask 320 and the third division structure may be partially removed by, e.g., a dry etching process to form a seventh opening 350 exposing the upper surface of the first substrate 100.

In example embodiments, lower and upper surfaces and a sidewall of an end portion in the second direction D2 of the first channel 125 may be exposed by the seventh opening 350.

For example, a thermal oxidation process may be performed to form a first gate insulation pattern 360 covering the lower and upper surfaces and the sidewall of the end portion of the first channel 125.

A first gate electrode layer may be formed on a sidewall and a bottom of the seventh opening 350 and the first gate insulation pattern 360, and a wet etching process or a dry etching process may be performed on the first gate electrode layer to form a first gate electrode 370 surrounding a portion of the first gate insulation pattern 360.

A first gate mask layer may be formed on the sidewall and the bottom of the seventh opening 350, the first gate insulation pattern 360 and the first gate electrode 370, a wet etching process or a dry etching process may be performed on the first gate mask layer to form a first gate mask 380 surrounding a portion of the first gate insulation pattern 360 and contacting a sidewall in the second direction D2 of the first gate electrode 370.

The first gate electrode 370, the first gate insulation pattern 360 and the first gate mask 380 collectively form a first gate structure on the first region I of the first substrate 100, and may extend in the first direction D2 to surround an end portion in the second direction D2 of each of the first channels 125 in the third region III. Thus, a plurality of first gate structures may be spaced apart from each other in the third direction D3 at each of opposite sides in the second direction D2 of the seventh opening 350. Each of the first gate structures may serve as a word line of the semiconductor device.

Referring to FIGS. 20 and 21 together with FIG. 28, a second gate structure including a second gate electrode 375, a second gate insulation pattern 365 and a second gate mask 385 may be formed on the second region II of the first substrate 100, and may extend in the first direction D1 to surround an end portion in the second direction D2 of each of the second channels 126. Thus, a plurality of second gate structures may be spaced apart from each other in the third direction D3 at each of opposite sides in the second direction D2 of the seventh opening 350.

A filling pattern may be formed to fill spaces between the first gate structures spaced apart from each other in the third direction D3 and between the second gate structures spaced apart from each other in the third direction D3, a third insulation layer and a fourth insulation layer may be sequentially stacked on a sidewall in the second direction D2 of each of the first and second gate structures adjacent to the seventh opening 350, a sidewall of the filling pattern and the upper surface of the first substrate 100 exposed by the seventh opening 350, a ninth division layer may be formed to fill the seventh opening 350, and a planarization process may be performed on the ninth division layer, the third insulation layer and the fourth insulation layer until the upper surface of the second mask layer 320 is exposed to form a ninth division pattern 410, a third insulation pattern and a fourth insulation pattern 400, respectively.

The filling pattern, the third insulation pattern and the ninth division pattern 410 may include an oxide, e.g., silicon oxide, and the fourth insulation pattern 400 may include an insulating nitride, e.g., silicon nitride. The filling pattern and the third insulation pattern may be merged with the seventh division pattern 310, and hereinafter, the merged structure may be referred to as the seventh division pattern 310.

The fourth insulation pattern 400 and the ninth division pattern 410 collectively form a fourth division structure 415.

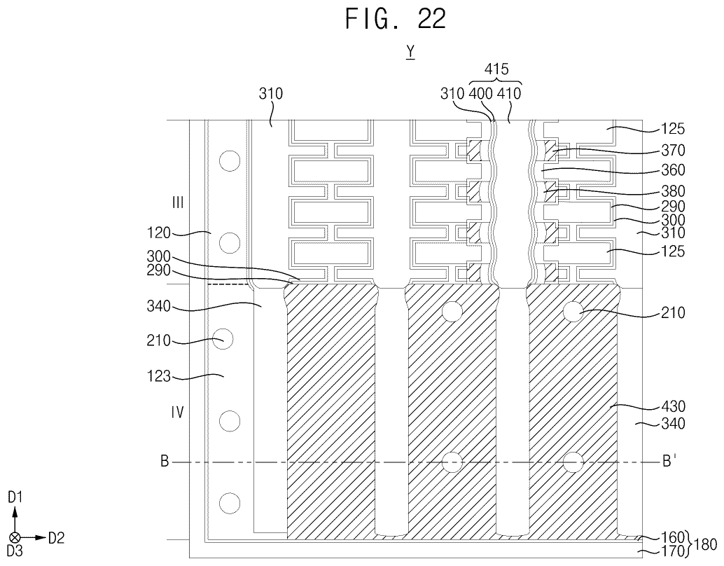

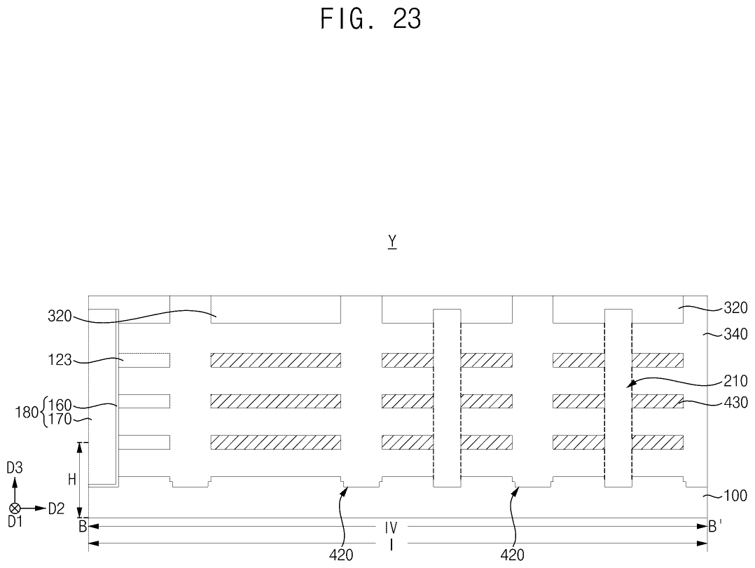

Referring to FIGS. 22 and 23, the eighth division pattern 340 may be removed by, e.g., a dry etching process to form an eighth opening 420 exposing the upper surface of the first substrate 100, and e.g., a wet etching process may be performed through the eighth opening 420 to remove the semiconductor pattern 123 to form a third gap, a conductive pad layer may be formed to fill the third gap, and e.g., a wet etching process may be performed on the conductive pad layer to form a conductive pad 430 in the third gap.

In example embodiments, the conductive pad 430 may extend in the first direction D1 in the fourth region IV, and a plurality of conductive pads 430 may be spaced apart from each other in the second direction D2. Additionally, a plurality of conductive pads 430 may be spaced apart from each other in the third direction D3.

A tenth division layer may be formed to fill the eighth opening 420, and a planarization process may be performed on the tenth division layer until the upper surface of the second mask 320 is exposed to form a tenth division pattern in the eighth opening 420. The tenth division pattern may include an insulating nitride, e.g., silicon nitride, and may contact the eighth division pattern 340 between the conductive pads 430 spaced apart from each other in the third direction D3 to be merged thereto. Hereinafter, the eighth division pattern 340 together with the tenth division pattern merged thereto may be referred to as the eighth division pattern 340.

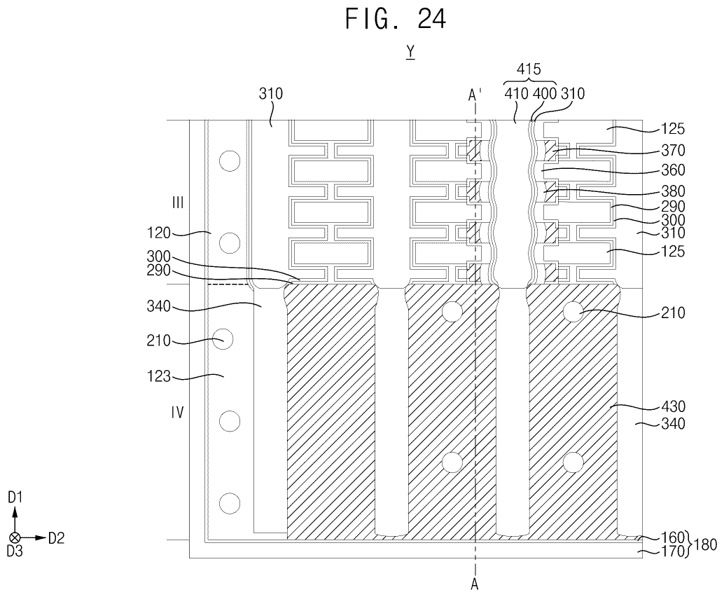

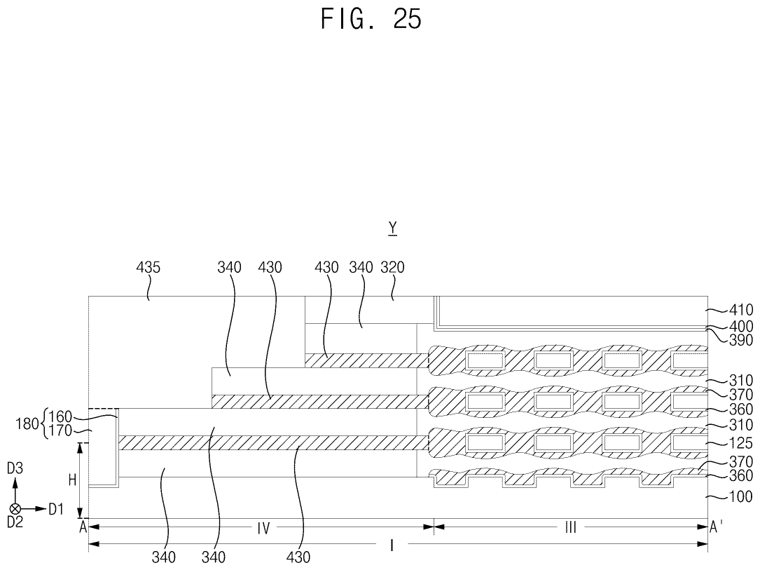

Referring to FIGS. 24 and 25, the second mask 320, the eighth division pattern 340 and the conductive pad 430 in the fourth region IV may be partially removed by, e.g., a dry etching process to form a ninth opening exposing an upper surface of the eighth division pattern 340.

In example embodiments, after the dry etching process, each of the conductive pads 430 and a portion of the eighth division pattern 340 thereon may collectively form a step layer extending in the first direction D1, and a stack structure including the conductive pads 430 and the eighth division patterns 340 may have a staircase structure having a length decreasing from a bottom toward a top thereof in a stepwise manner. During the dry etching process, upper portions of the first and second division patterns 160 and 170 contacting an end portion in the first direction D1 of the conductive pad 430 may also be removed.

A second insulating interlayer 435 may be formed to fill the ninth opening. The second insulating interlayer 435 may include an oxide, e.g., silicon oxide, and in some embodiments, may be merged to the second division pattern 170.

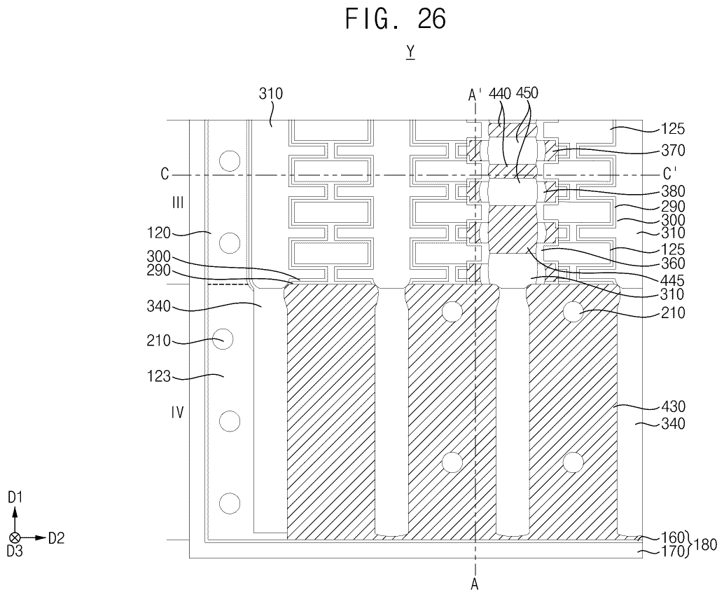

Referring to FIGS. 26 to 28, the fourth division structure 415 and the seventh division pattern 310 may be partially etched by, e.g., a dry etching process on the first region I of the first substrate 100 to form a first trench, a bit line layer may be formed in the first trench, and the bit line layer may be patterned to form a bit line 440.

As the first trench is formed, end portions in the second direction D2 of the first channels 125, the first gate insulation patterns 360 and the first gate masks 380 that are disposed in the third direction D3 at each of opposite sides in the second direction D2 of the fourth division pattern 415 may be exposed, and thus the bit line 440 extending in the third direction D3 in the first trench may contact the first channels 125, the first gate insulation patterns 360 and the first gate masks 380.

In example embodiments, a plurality of bit lines 440 may be spaced apart from each other in the first direction D1 in the third region III, and the plurality of bit lines 440 may contact the first channels 125, respectively, disposed in the first direction D1 to be electrically connected thereto. However, one of the bit lines 440 disposed in the first direction D1 that is adjacent to the fourth region IV may be a dummy bit line 445.

In an example embodiment, the bit line 440 may include polysilicon doped with n-type impurities. Alternatively, the bit line 440 may include, e.g., a metal, a metal nitride, a metal silicide, etc.

Additionally, the fourth division structure 415 and the seventh division pattern 310 on the second region II of the first substrate 100 may be partially removed by, e.g., a dry etching process to form a second trench, a source/drain layer may be formed in the second trench, and may be patterned to form a first source/drain pattern 460.

As the second trench is formed, end portions in the second direction D2 of the second channels 126, the second gate insulation patterns 365 and the second gate masks 385 that are disposed in the third direction D3 at each of opposite sides in the second direction D2 of the fourth division pattern 415 may be exposed, and thus the first source/drain pattern 460 extending in the third direction D3 in the second trench may contact the second channels 126, the second gate insulation patterns 365 and the second gate masks 385. Two first source/drain patterns 460 spaced apart from each other in the second direction D2 may be formed on a portion of the fourth division structure 415 contacting the upper surface of the first substrate 100

In example embodiments, a plurality of first source/drain patterns 460 may be spaced apart from each other in the first direction D1 on the second region II of the first substrate 100, and the plurality of first source/drain patterns 460 may contact the second channels 126, respectively, disposed in the first direction D1 to be electrically connected thereto.

In an example embodiment, the first source/drain pattern 460 may include polysilicon doped with n-type impurities. Alternatively, the first source/drain pattern 460 may include polysilicon doped with p-type impurities.

An eleventh division pattern 450 filling a space between the bit lines 440 disposed in the first direction D1 may be formed on the first region I of the first substrate 100, and a twelfth division pattern 455 filling a space between the first source/drain patterns 460 disposed in each of the first and second directions D1 and D2 may be formed on the second region II of the first substrate 100. Each of the eleventh and twelfth division patterns 450 and 455 may include an oxide, e.g., silicon oxide.

The second mask 320, the third division structure and the second channel 126 on the second region II of the first substrate 100 may be partially removed by, e.g., a dry etching process to form a third trench, and a second source/drain pattern 465 may be formed in the third trench. The second source/drain pattern 465 may extend in the third direction D3, and may contact end portions in the second direction D2 of ones of the second channels 126 disposed in the third direction D3.

In example embodiments, a plurality of second source/drain patterns 465 may be spaced apart from each other in the first direction D1 on the second region II of the first substrate 100, and may overlap the first source/drain patterns 460, respectively, in the second direction D2. The second gate structure, the second channel 126 and the first and second source/drain patterns 460 and 465 may collectively form a first transistor.

In an example embodiment, the second source/drain pattern 465 may include polysilicon doped with n-type impurities. Alternatively, the second source/drain pattern 465 may include polysilicon doped with p-type impurities.

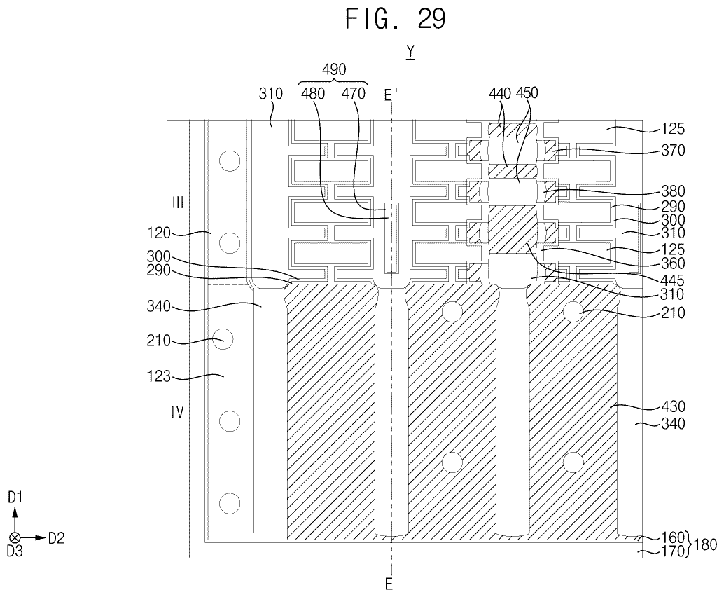

Referring to FIGS. 29 and 30, the seventh division pattern 310 may be partially removed by, e.g., a dry etching process to form a tenth opening exposing the upper surface of the first substrate 100, and a blocking structure 490 may be formed in the tenth opening.

In example embodiments, the blocking structure 490 may be formed in a portion of the third region III adjacent to the fourth region IV, and may be disposed between ones of the first channels 125 neighboring in the second direction D2 at an opposite side in the second direction D2 of the bit line 440 with respect to the first channel 125.

In an example embodiment, the blocking structure 490 may include a first blocking pattern 470 on a sidewall and a bottom of the tenth opening and a second blocking pattern 480 filling a remaining portion of the tenth opening. A sidewall and a lower surface of the second blocking pattern 480 may be covered by the first blocking pattern 470. The first blocking pattern 470 may include an insulating nitride, e.g., silicon nitride, and the second blocking pattern 480 may include an oxide, e.g., silicon oxide.

In an example embodiment, the blocking structure 490 may have a shape of a polygon, e.g., a rectangle in a plan view, however, inventive concepts are not limited thereto.

A capping layer 500 may be formed on the blocking structure 490, the bit line 440, the dummy bit line 445, the first and second source/drain patterns 460 and 465, the second insulating interlayer 435, the second mask 320, the seventh division pattern 310, the fourth division structure 415 and the eleventh and twelfth division patterns 450 and 455. The capping layer 500 may include an insulating nitride, e.g., silicon nitride.

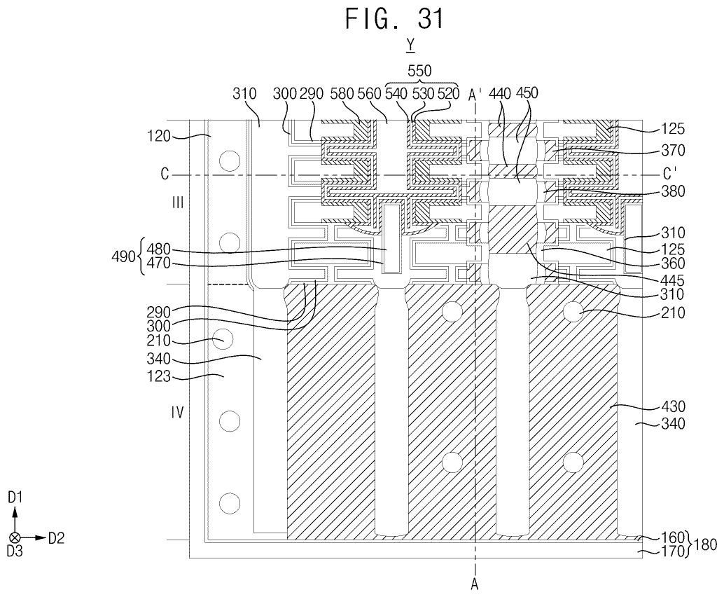

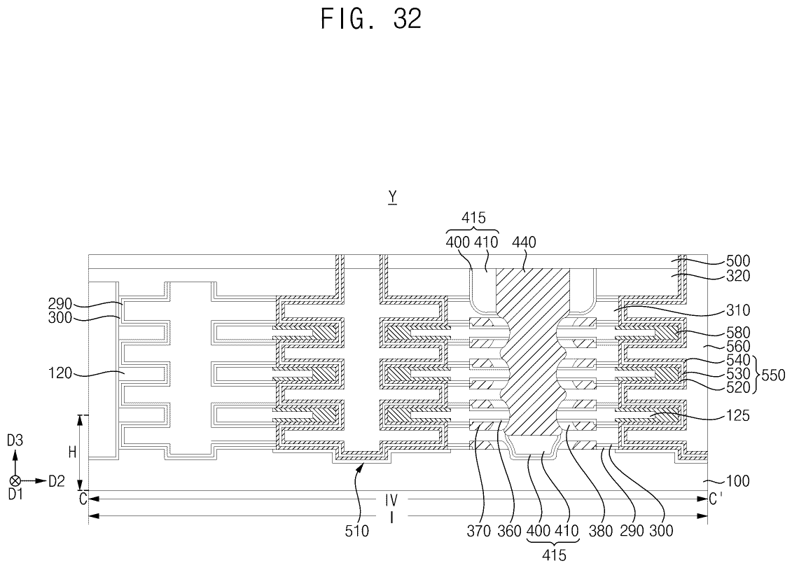

Referring to FIGS. 31 and 32, the capping layer 500, the second mask 320 and the third division structure may be partially removed by, e.g., a dry etching process to form an eleventh opening 510 exposing the upper surface of the first substrate 100.

In example embodiments, the eleventh opening 510 may expose a sidewall in the first direction D1 of the blocking structure 490.

For example, a wet etching process may be performed through the eleventh opening 510 to remove a portion of the seventh division pattern 310 between the first channels 125 adjacent to the eleventh opening 510 to form a fourth gap. During the wet etching process, portions of the first and second insulation patterns 290 and 300 on lower and upper surfaces and a sidewall of a portion of the first channel 125 may also be removed to expose the portion of the first channel 125.

A first capacitor electrode layer, a dielectric layer and a second capacitor electrode layer may be sequentially stacked on an inner wall of the fourth gap, an inner wall of the eleventh opening 510 and an upper surface of the capping layer 500, a plate electrode layer may be formed on the second capacitor electrode layer to fill the fourth gap and the eleventh opening 510, and a planarization process may be performed on the plate electrode layer, the first and second capacitor electrode layers and the dielectric layer until the upper surface of the capping layer 500 is exposed to form a plate electrode 560, first and second capacitor electrodes 520 and 540 and a dielectric pattern 530, respectively, in the fourth gap and the eleventh opening 510.

When the first capacitor electrode layer is formed, a metal silicide pattern 580 may be formed at a portion of the first channel 125 contacting the first capacitor electrode layer.

The first and second capacitor electrodes 520 and 540 and the dielectric pattern 530 may collectively form a capacitor 550, and the capacitor 550 and together with the plate electrode 560 may collectively form a capacitor structure.

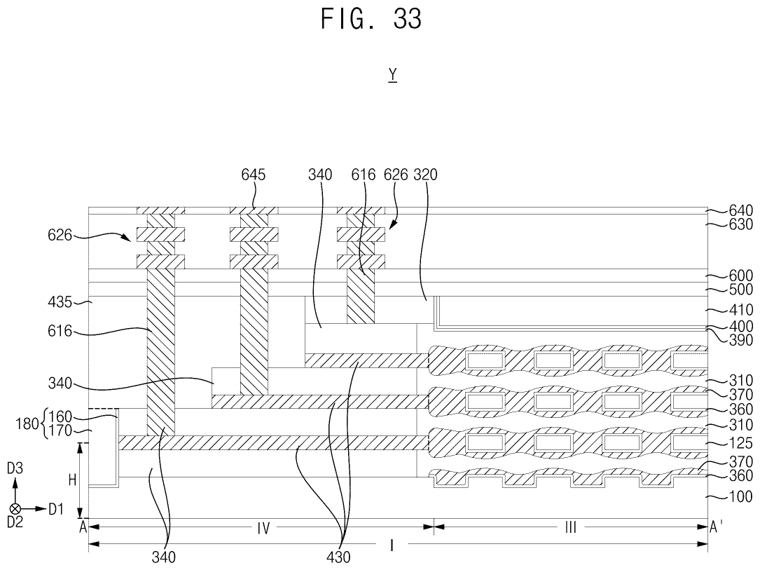

Referring to FIGS. 33 to 35, a third insulating interlayer 600 may be formed on the capacitor structure and the capping layer 500, a first contact plug extending through the third insulating interlayer 600 and the capping layer 500 to contact an upper surface of the bit line 440, a second contact plug extending through the third insulating interlayer 600 to contact an upper surface of the capacitor structure, a third contact plug extending through the third insulating interlayer 600, the capping layer 500, the second mask 320 and the eighth division pattern 340 or the third insulating interlayer 600, the capping layer 500 and the second insulating interlayer 435 to contact an upper surface of the conductive pad 430, and fourth and fifth contact plugs 618 and 619 extending through the third insulating interlayer 600 and the capping layer to contact upper surfaces of the first and second source/drain patterns 460 and 465, respectively, may be formed.

First to fifth wiring structures 622, 624, 626, 628 and 629 may be formed on the third insulating interlayer 600 and the first to fifth contact plugs 612, 614, 616, 618 and 619, a fourth insulating interlayer 630 may be formed to cover the first to fifth wiring structures 622, 624, 626, 628 and 629, and a first bonding layer 640 including a first bonding pattern 645 may be formed on the fourth insulating interlayer 630.

Referring to FIGS. 1 to 8 again, second and third transistors may be formed on the first and second regions I and II, respectively, of the second substrate 700.

The second transistor may include a third gate structure 730 having a third gate insulation pattern 710 and a third gate electrode 720, and first impurity regions 705 at portions of the second substrate 700 adjacent to the third gate structure 730, and the third transistor may include a fourth gate structure 735 having a fourth gate insulation pattern 715 and a fourth gate electrode 725, and second impurity regions 707 at portions of the second substrate 700 adjacent to the fourth gate structure 735.

A fifth insulating interlayer 740 may be formed to cover the second and third transistors, and sixth and seventh contact plugs 750 and 755 extending through the fifth insulating interlayer 740 to contact the first and second impurity regions 705 and 707, respectively, may be formed.

Sixth and seventh wiring structures 800 and 810 may be formed on the fifth insulating interlayer 740, a sixth insulating interlayer 820 may be formed on the fifth insulating interlayer 740 to cover the sixth and seventh wiring structures 800 and 810, and a second bonding layer 830 including a second bonding pattern 835 may be formed on the sixth insulating interlayer 820.

After flipping the second substrate 700, the first and second substrates 100 and 700 may be bonded with each other by contacting the second bonding layer 830 to the first bonding layer 640, and the first and second bonding patterns 645 and 835 may contact each other.

By the above processes, the semiconductor device may be manufactured.

As illustrated above, memory cells including the first channel 125, the word line, the bit line 440 and the capacitor structure may be formed on the first region I of the first substrate 100, and the first transistors each of which may include the second channel 126, the second gate structure and the first and second source/drain patterns 460 and 465 may be formed by processes substantially the same as or similar to those of the memory cells.

The second channel 126, the second gate structure and the first source/drain pattern 460 of each of the first transistor may be formed together with the first channel 125, the word line and the bit line 440, respectively. Thus, each of the first transistors may be formed by the processes for forming the memory cells, so that additional processes are not needed and/or are reduced.

While inventive concepts has been shown and described with reference to some example embodiments thereof, it will be apparent to those of ordinary skill in the art that various modifications in form and details may be made thereto without departing from the spirit and scope of inventive concepts as set forth by the following claims.

What is claimed is:

1. A semiconductor device, comprising:
a substrate including a first region and a second region;
a first channel on the first region of the substrate;
a first gate structure surrounding a portion of the first channel;
a bit line at a first side of the first channel, the bit line being electrically connected to the first channel;
a capacitor at a second side of the first channel, the capacitor being electrically connected to the first channel;
a second channel on the second region of the substrate;
a second gate structure surrounding a portion of the second channel;
a first source/drain pattern at a first side of the second channel, the first source/drain pattern being electrically connected to the second channel; and
a second source/drain pattern at a second side of the second channel, the second source/drain pattern being electrically connected to the second channel, wherein
a height of the first channel from an upper surface of the substrate is equal to a height of the second channel from the upper surface of the substrate.

2. The semiconductor device of claim 1, wherein a material in the bit line is the same as a material in the first source/drain pattern and a material in the second source/drain pattern.

3. The semiconductor device of claim 2, wherein the bit line, the first source/drain pattern, and the second source/drain pattern include polysilicon doped with n-type impurities.

4. The semiconductor device of claim 1, wherein
an upper surface of the bit line is coplanar with an upper surface of the first source/drain pattern, and
a lower surface of the bit line is coplanar with a lower surface of the first source/drain pattern.

5. The semiconductor device of claim 1, wherein the first gate structure includes:
a first gate insulation pattern surrounding the portion of the first channel;
a first gate electrode surrounding a portion of the first gate insulation pattern; and
a first gate mask surrounding a portion of the first gate insulation pattern and contacting the first gate electrode.

6. The semiconductor device of claim 5, wherein the bit line contacts the first gate insulation pattern and the first gate mask.

7. The semiconductor device of claim 1, wherein the second gate structure includes:
a second gate insulation pattern surrounding the portion of the second channel;
a second gate electrode surrounding a portion of the second gate insulation pattern; and
a second gate mask surrounding a portion of the second gate insulation pattern and contacting the second gate electrode.

8. The semiconductor device of claim 7, wherein the first source/drain pattern contacts the second gate insulation pattern and the second gate mask.

9. The semiconductor device of claim 1, wherein a height of the first gate structure from an upper surface of the substrate is equal to a height of the second gate structure from the upper surface of the substrate.

10. The semiconductor device of claim 1, wherein
the bit line contacts the first channel, and
the first source/drain pattern and the second source/drain pattern each contact the second channel.

11. The semiconductor device of claim 1, further comprising:
a metal silicide pattern between the first channel and the capacitor, wherein
the capacitor includes a first capacitor electrode, a dielectric pattern, and a second capacitor electrode sequentially stacked on a surface of the first channel.

12. A semiconductor device, comprising:
a substrate including a first region and a second region;
first channels extending in a first direction on the first region of the substrate and spaced apart from each other in a second direction, the first direction being parallel to an upper surface of the substrate, and the second direction being perpendicular to the upper surface of the substrate;
first gate structures disposed in the second direction, each of the first gate structures extending in a third direction, the third direction being parallel to the upper surface of the substrate and crossing the first direction, and the first gate structures surrounding portions of the first channels, respectively;
a bit line extending in the second direction on the substrate at a first side in the first direction of each of the first channels, the bit line being electrically connected to the first channels;
a capacitor at a second side in the first direction of each of the first channels, the capacitor being electrically connected to the first channels;
second channels on the second region of the substrate, each of the second channels extending in the first direction, and the second channels being spaced apart from each other in the second direction;
second gate structures disposed in the second direction, each of the second gate structures extending in the third direction, and the second gate structures surrounding portions of the second channels, respectively;
a first source/drain pattern at a first side in the first direction of each of the second channels on the substrate, the first source/drain pattern being electrically connected to the second channels; and
a second source/drain pattern at a second side in the first direction of each of the second channels on the substrate, the second source/drain pattern being electrically connected to the second channels,
wherein the first channels and corresponding ones of the second channels are respectively at same heights from an upper surface of the substrate.

13. The semiconductor device of claim 12, wherein
a plurality of the first channels are at a same height from the upper surface of the substrate and form a first channel column, and
the first gate structures surround the portions of the plurality of the first channels included in the first channel column.

14. The semiconductor device of claim 12, wherein
a plurality of the second channels are at a same height from the upper surface of the substrate and form a second channel column, and
the second gate structures surround the portions of the plurality of the second channels included in the second channel column.

15. The semiconductor device of claim 12, further comprising:
a conductive pad contacting an end portion in the third direction of each of the first gate structures.

16. A semiconductor device, comprising:
a first substrate;
a second substrate;
first channels on a memory cell region of the first substrate, the first substrate including the memory cell region and a first peripheral circuit region, each of the first channels extending in a first direction, the first direction being parallel to an upper surface of the first substrate, and the first channels being spaced apart from each other in a second direction, the second direction being perpendicular to the upper surface of the first substrate;
first gate structures disposed in the second direction, each of the first gate structures extending in a third direction, the third direction being parallel to the upper surface of the first substrate and crossing the first direction, and the first gate structures surrounding portions of the first channels, respectively;
conductive pads contacting end portions of the first gate structures, respectively, each of the conductive pads extending in the third direction;
a bit line extending in the second direction on the first substrate at a first side in the first direction of each of the first channels, the bit line being electrically connected to the first channels;
a capacitor structure at a second side in the first direction of each of the first channels, the capacitor structure being electrically connected to the first channels;
second channels on the first peripheral circuit region of the first substrate, each of the second channels extending in the first direction, and the second channels being spaced apart from each other in the second direction;
second gate structures disposed in the second direction, each of the second gate structures extending in the third direction, and the second gate structures surrounding portions of the second channels, respectively;
a first source/drain pattern extending in the second direction on the first substrate at a first side in the first direction of each of the second channels, the first source/drain pattern being electrically connected to the second channels;
a second source/drain pattern extending in the second direction on the first substrate at a second side in the first direction of each of the second channels, the second source/drain pattern being electrically connected to the second channels;
wiring structures electrically connected to the bit line, the capacitor structure, the conductive pads, the first source/drain pattern, and the second source/drain pattern; and
a first transistor and a second transistor on the wiring structures, the first transistor and the second transistor respectively being under a core region of the second substrate and a second peripheral circuit region of the second substrate, the second substrate including the core region and the second peripheral circuit region over the memory cell region and the first peripheral circuit region, respectively, of the first substrate, and the first transistor and the second transistor being electrically connected to the wiring structures.

17. The semiconductor device of claim 16, wherein
a plurality of the first channels are at a same height from the upper surface of the first substrate and form a first channel column, and
the first gate structures surround the portions of the plurality of the first channels included in the first channel column.

18. The semiconductor device of claim 16, wherein
a plurality of the second channels are at a same height from the upper surface of the first substrate and form a second channel column, and
the second gate structures surround the portions of the plurality of the second channels in the second channel column.

19. The semiconductor device of claim 18, wherein
the second channel column is one among a plurality of second channel columns in the first direction,
the first source/drain pattern is one among two first source/drain patterns spaced apart from each other in the first direction between neighboring ones of the plurality of second channel columns in the first direction.

20. The semiconductor device of claim 16, wherein lengths in the third direction of the conductive pads decrease from lowermost one of the conductive pads to an uppermost one of the conductive pads in a stepwise manner.
